(19) United States
(12) Patent Application Publication
(10) Pub. No.: US 2026/0291436 A1
(43) Pub. Date: Sep. 24, 2026

(54) CIRCUITS AND METHODS FOR GENERATING AN OSCILLATOR SIGNAL

(71) Applicant: Analog Devices International Unlimited Company, Limerick (IE)

(72) Inventors: Niall Kearney, County Cork (IE); Brendan O'Regan, Bandon (IE)

(21) Appl. No.: 19/477,377

(22) PCT Filed: Apr. 21, 2023
(86) PCT No.: PCT/EP2023/060511

§ 371 Date: Oct. 21, 2025

(51) Int. Cl. H03B 5/12

(52) U.S. Cl. CPC H03B 5/1212

(57) ABSTRACT

The present disclosure relates to an oscillator circuit comprising: a controller configured to generate a frequency control signal, the frequency control signal comprising a first frequency control value; a digitally controlled oscillator (DCO) configured to generate, based on the frequency control signal, an oscillator output signal, wherein the output signal is generated at a first frequency in response to the first frequency control value of the frequency control signal; and a digital feedback circuit configured to receive the output signal and output a first feedback signal, wherein the oscillator circuit is configured such that the first frequency is dependent on, or based at least in part on, a value of the first feedback signal, wherein the controller is configured provide a first control instruction to instruct the digital feedback circuit to update the first feedback signal, wherein the digital feedback circuit is configured to, in response to the first control instruction: measure the first frequency of the output signal; and adjust the value of the first feedback signal to reduce an error between the first frequency and a first target frequency.

### TECHNICAL FIELD

The present disclosure relates to an oscillator circuit for generating an oscillator signal, and methods of generating oscillator signals. In particular, the present disclosure relates to circuits and methods for generating an oscillator signal in co-operation with spread-spectrum modulation (SSM) and on-off keying (OOK) modulation schemes.

### BACKGROUND

Digital frequency locked loops (DFLLs) can be used to maintain a frequency of an output signal of an oscillator at a predetermined, target frequency. However, DFLLs are typically designed to run continuously once the system is powered on.

In some scenarios, the output signal of the oscillator may have a discontinuous profile. For example, the output signal may have a discontinuous frequency profile, e.g. if the oscillator is being controlled in accordance with a spread-spectrum modulation scheme. However, DFLLs which are designed to run continuously may not be used in combination with such an oscillator, since the DFLL is not equipped to interpret the constantly changing frequency of the output signal.

In another example, the output signal may have a discontinuous amplitude profile, e.g. if the oscillator is being controlled in accordance with an on-off key (OOK) amplitude modulation scheme. In particular, the oscillator may be toggling between an on state and an off state. However, again, typical DFLLs may not be equipped to interpret the constantly changing amplitude of the oscillator signal. In particular, DFLLs may not be equipped to handle when the oscillator is turned off. Furthermore, the act of turning on and off the oscillator according to OOK modulation results in a discontinuous oscillator phase trajectory, meaning that phase locked loop (PLL) approaches are unsuitable.

### SUMMARY OF THE DISCLOSURE

According to a first aspect of the present disclosure, there is provided an oscillator circuit comprising: a controller configured to generate a frequency control signal, the frequency control signal comprising a first frequency control value; a digitally controlled oscillator (DCO) configured to generate, based on the frequency control signal, an oscillator output signal, wherein the output signal is generated at a first frequency in response to the first frequency control value of the frequency control signal; and a digital feedback circuit configured to receive the output signal and output a first feedback signal, wherein the oscillator circuit is configured such that the first frequency is dependent on, or based at least in part on, a value of the first feedback signal, wherein the controller is configured provide a first control instruction to instruct the digital feedback circuit to update the first feedback signal, wherein the digital feedback circuit is configured to, in response to the first control instruction: measure the first frequency of the output signal; and adjust the value of the first feedback signal to reduce an error between the first frequency and a first target frequency.

In some examples, the controller is configured to discontinuously or aperiodically provide the first control instruction to the digital feedback circuit.

In some examples, the digital feedback circuit is configured to adjust the value of the first feedback signal in response to an update control instruction, optionally wherein the controller is configured to provide the update control instruction at a different time to providing the first control instruction.

In some examples, the frequency control signal comprises a sequence of discrete frequency control values ranging from the first frequency control value to a second frequency control value, wherein the DCO is configured to generate the output signal at an instantaneous frequency corresponding to a current value of the frequency control signal, wherein the controller is configured provide the first control instruction when the current value of the frequency control signal corresponds to the first frequency control value.

In some examples, the oscillator circuit further comprises a second digital feedback circuit configured to receive the output signal and output a second feedback signal, wherein the controller is configured to receive the first feedback signal and the second feedback signal and generate the frequency control signal based on the first feedback signal and the second feedback signal, wherein the first frequency control value is proportional to the value of the first feedback signal and the second frequency control value is proportional to a value of the second feedback signal, wherein the output signal is generated at a second frequency in response to the second frequency control value of the frequency control signal, wherein the controller is further configured to provide a second control instruction to instruct the second digital feedback circuit to update the second feedback signal, wherein the controller is configured to provide the second control instruction when the current value of frequency control signal corresponds to the second frequency control value, wherein the second digital feedback circuit is configured to, in response to the second control instruction: measure of the second frequency of the output signal; and adjust the value of the second feedback signal to reduce an error between the second frequency and a second target frequency.

In some examples, the digital feedback circuit is configured to, in response to the first control instruction: measure the first frequency within a time window initiated by the first control instruction, determine an error between the first frequency and the first target frequency; and adjust the value of the first feedback signal based on the determined error. In some examples, adjusting the value of the first feedback signal comprises: increasing the value of the first feedback signal if the error indicates that the first frequency is less than the first target frequency; and decreasing the value of the first feedback signal if the error indicates that the first frequency is greater than the first target frequency.

In some examples, adjusting the value of the first feedback signal comprises: increasing the value of the first feedback signal if the error indicates that the first frequency is less than the first target frequency by a first threshold amount; and decreasing the value of the first feedback signal if the error indicates that the first frequency is greater than the first target frequency by a second threshold amount.

In some examples, adjusting the value of the first feedback signal comprises: if the error is greater than a previous error between the first frequency and the first target frequency, then: increasing the value of the first feedback signal if the error indicates that the first frequency is less than the first target frequency, and decreasing the value of the first feedback signal if the error indicates that the first frequency is greater than the first target frequency by a first threshold amount; and if the error is less than the previous error, then: increasing the value of the first feedback signal if the error indicates that the first frequency is less than the first target frequency by a second threshold amount, and decreasing the value of the first feedback signal if the error indicates that the first frequency is greater than the first target frequency.

In some examples, the digital feedback circuit is configured to output a second feedback signal, wherein the controller is further configured to receive the first feedback signal and the second feedback signal and generate the frequency control signal based on the first feedback signal and the second feedback signal, wherein the first frequency control value is proportional to the value of the first feedback signal and the second frequency control value is proportional to a value of the second feedback signal, wherein the output signal is generated at a second frequency in response to the second frequency control value of the frequency control signal, wherein the controller is configured to provide the first control instruction when the current value of frequency control signal corresponds to the first frequency control value, and provide a second control instruction to instruct the digital feedback circuit to update the second feedback signal, wherein the controller provides the second control instruction when the current value of frequency control signal corresponds to the second frequency control value, wherein the digital feedback circuit is configured to, in response to the second control instruction: measure the second frequency of the output signal; and adjust the value of the second feedback signal to reduce an error between the second frequency and the second target frequency.

In some examples, the digital feedback circuit is configured to: in response to the first control instruction: measure, using a frequency estimation circuit, the first frequency within a time window initiated by the first control instruction, determine, using a digital subtractor, an error between the first frequency and the first target frequency; and adjust the value of the first feedback signal based on the determined error; and in response to the second control instruction: measure, using the frequency estimation circuit, the second frequency within a time window initiated by the second control instruction, determine, using the digital subtractor, an error between the second frequency and a second target frequency; and adjust the value of the first feedback signal based on the determined error. In some examples, the digital feedback circuit further comprises a multiplexer configured to provide the first target frequency to the subtractor in response to the first control instruction, and provide the second target frequency to the subtractor in response to the second control instruction.

In some examples, the digital feedback circuit is configured to: in response to the first control instruction: generate, using an error processing circuit and based on the error between the first frequency and the first target frequency, an adjustment value indicative of a desired adjustment to the value of the first feedback signal to reduce the error, and adjust the first feedback signal by adding, using a digital adder, the adjustment value to the first feedback signal; and in response to the second control instruction: generate, using the error processing circuit and based on the error between the second frequency and the second target frequency, an adjustment value indicative of a desired adjustment to the value of the second feedback signal to reduce the error, and adjust the second feedback signal by adding, using the digital adder, the adjustment value to the second feedback signal.

In some examples, the digital feedback circuit further comprises: a first output configured to output the first feedback signal and a second output to output the second feedback signal; and a multiplexer configured to provide the first feedback signal from the first output to the adder in response to the first control instruction, and provide the second feedback signal from the second output to the adder in response to the second control instruction.

In some examples, the controller is configured to provide a clock signal to the DCO, wherein the DCO is configured to toggle between an on state and an off state in response to the clock signal; and wherein the controller is configured to provide the first control instruction when the DCO is in the on-state.

In some examples, wherein the clock signal is a pulse-width modulated (PWM) clock signal, the PWM signal having a duty cycle defining an on-time of the PWM signal, wherein the DCO is configured to be in the on state during the on-time of the PWM signal.

In some examples, the controller is configured to provide the first control instruction when the DCO is in the on-state and when the duty cycle of the PWM signal is above a threshold duty cycle.

In some examples, the DCO is configured to receive the first feedback signal, and apply a frequency offset to the output signal based on the first feedback signal, wherein the frequency offset is proportional to the value of the first feedback signal.

According to a second aspect of the present disclosure, there is provided an oscillator circuit comprising: a digitally controlled oscillator (DCO) configured to generate an oscillator output signal at a first frequency; a digital feedback circuit configured to receive the output signal and output a feedback signal, wherein the DCO is configured to receive the feedback signal, and wherein the first frequency of the output signal is based at least in part on a value of the feedback signal; wherein the digital feedback circuit is configured to, in response to a control instruction: measure the first frequency of the output signal; and adjust the value of the feedback signal to reduce an error between the first frequency and a target frequency.

In some examples, the oscillator circuit further comprises a controller, wherein the controller is configured to discontinuously or aperiodically provide the control instruction to the digital feedback circuit.

In some examples, the digital feedback circuit is configured to adjust the value of the feedback signal in response to an update control instruction, optionally wherein the controller is configured to provide the update control instruction at a different time to providing the control instruction.

In some examples, the oscillator circuit further comprises a controller, wherein the controller is configured to provide a clock signal to the DCO, wherein the DCO is configured to toggle between an on state and an off state in response to the clock signal; and wherein the controller is configured to provide the control instruction to digital feedback circuit when the DCO is in the on-state.

In some examples, the clock signal is a pulse-width modulated (PWM) clock signal, the PWM signal having a duty cycle defining an on-time of the PWM signal, wherein the DCO is configured to be in the on state during the on-time of the PWM signal.

In some examples, the controller is configured to provide the control instruction when the DCO is in the on-state and when the duty cycle of the PWM signal is above a threshold duty cycle.

In some examples, the DCO is configured to: receive a frequency control signal comprising a first frequency control value, wherein the output signal is generated at the first frequency in response to the first frequency control value of the frequency control signal; and apply a frequency offset to the output signal based on the first feedback signal, wherein the frequency offset is proportional to the value of the first feedback signal.

In some examples, the frequency control signal comprises a sequence of discrete frequency control values ranging from the first frequency control value to a second frequency control value, wherein DCO is configured to generate the output signal at an instantaneous frequency corresponding to a current value of the frequency control signal, wherein the controller is configured provide the control instruction to the digital feedback circuit when the current value of frequency control signal corresponds to the first frequency control value.

In some examples, the DCO is configured to generate the output signal at the first frequency in response to the value of the feedback signal, wherein the first frequency is proportional to the value of the feedback signal.

In some examples, the digital frequency circuit is configured to, in response to the control instruction: measure the first frequency within a time window initiated by the control instruction, determine an error between the first frequency and the target frequency; and adjust the value of the feedback signal based on the determined error.

In some examples, adjusting the value of the feedback signal comprises: increasing the value of the feedback signal if the error indicates that the first frequency is less than the target frequency; and decreasing the value of the feedback signal if the error indicates that the first frequency is greater than the target frequency.

In some examples, adjusting the value of the feedback signal comprises: increasing the value of the feedback signal if the error indicates that the first frequency is less than the target frequency by a first threshold amount; and decreasing the value of the feedback signal if the error indicates that the first frequency is greater than the target frequency by a second threshold amount.

In some examples, adjusting the value of the feedback signal comprises: if the error is greater than a previous error between the first frequency and the target frequency, then: increasing the value of the feedback signal if the error indicates that the first frequency is less than the target frequency, and decreasing the value of the feedback signal if the error indicates that the first frequency is greater than the target frequency by a first threshold amount; and if the error is less than the previous error, then: increasing the value of the feedback signal if the error indicates that the first frequency is less than the target frequency by a second threshold amount, and decreasing the value of the feedback signal if the error indicates that the first frequency is greater than the target frequency.

According to a third aspect of the present disclosure, there is provided a method of generating an oscillator output signal, comprising: generating, based on a frequency control signal, an oscillator output signal, the frequency control signal comprising a first frequency control value, wherein the output signal is generated at a first frequency in response to the first frequency control value of the frequency control signal, wherein the first frequency is dependent on, or based at least in part on, a value of the first feedback signal; and in response to a first control instruction: measuring the first frequency of the output signal; and adjusting the value of the first feedback signal to reduce an error between the first frequency and a first target frequency.

According to a fourth aspect of the present disclosure, there is provided a method of generating an oscillator output signal, comprising: generating, based on a feedback signal, an oscillator output signal at a first frequency, wherein the first frequency of the output signal is based at least in part on a value of the feedback signal; in response to a control instruction: measuring the first frequency of the output signal; and adjusting the value of the feedback signal to reduce an error between the first frequency and a target frequency. According to another aspect, there is provided a galvanically isolated power transfer circuit, comprising: a first circuit region and a second circuit region separated by a galvanic isolation barrier, the first circuit region comprising the oscillator circuit of any previous aspects; a first transformer configured to transfer the oscillator output signal across the isolation barrier to the second circuit region; and wherein the second circuit region comprises powered circuitry configured to receive a voltage supply signal that is based on the transferred oscillator output signal.

In some examples, the DCO is configured to receive a pulse-width modulated (PWM) clock signal, the PWM signal having a duty cycle defining an on-time of the PWM signal, wherein the DCO is configured to be in an on state during the on-time of the PWM signal. The power transfer circuit further comprises a feedback circuit configured to receive the voltage supply signal and adjust the duty cycle of the PWM signal to maintain the voltage supply signal at a reference voltage signal.

### BRIEF DESCRIPTION OF THE DRAWINGS

FIG. 1 shows a digitally controlled oscillator (DCO) according to an example of the present disclosure;

FIG. 2 shows a frequency control mapping of the DCO of FIG. 1;

FIG. 3 shows an oscillator circuit according to an example of the present disclosure;

FIG. 4 shows a digital feedback circuit according to an example of the present disclosure;

FIG. 5 shows a frequency measurement circuit according to an example of the present disclosure;

FIG. 6 shows a timing diagram that illustrates the operation of the frequency measurement circuit of FIG. 5;

FIGS. 7A-7B show a feedback signal generator circuit according to an example of the present disclosure;

FIGS. 8A-8C show transfer functions of bang-bang detectors, according to examples of the present disclosure;

FIGS. 9A-9B show example emissions spectra of the output signal of the oscillator circuit;

FIG. 10 shows an oscillator circuit according to another example of the present disclosure;

FIG. 11A shows an example frequency control signal;

FIG. 11B shows an example frequency spectrum of an output signal of the oscillator circuit of FIG. 10;

FIGS. 12A-12B show example emissions spectra of the output signal of the oscillator circuit;

FIG. 13 shows an oscillator circuit according to another example of the present disclosure;

FIG. 14 shows an oscillator circuit according to another example of the present disclosure;

FIG. 15 shows a digital feedback circuit according to another example of the present disclosure;

FIGS. 16A-16C show a feedback signal generator circuit according to another example of the present disclosure;

FIGS. 17A-17B show example emissions spectra of the output signal of the oscillator circuit;

FIG. 18 shows an oscillator circuit according to another example of the present disclosure;

FIG. 19 shows an example PWM signal for controlling a DCO according to an on-off keying (OOK) modulation scheme;

FIG. 20 shows an oscillator circuit according to another example of the present disclosure;

FIG. 21 shows an oscillator circuit according to another example of the present disclosure;

FIG. 22 shows an example emissions spectrum of the output signal of the oscillator circuit;

FIG. 23 shows an oscillator circuit according to another example of the present disclosure;

FIG. 24 shows an oscillator circuit according to another example of the present disclosure;

FIGS. 25-28 show example DCO circuits, according to examples of the present disclosure; and

FIG. 29 shows a galvanically isolated power transfer circuit according to an example of the present disclosure.

### DETAILED DESCRIPTION

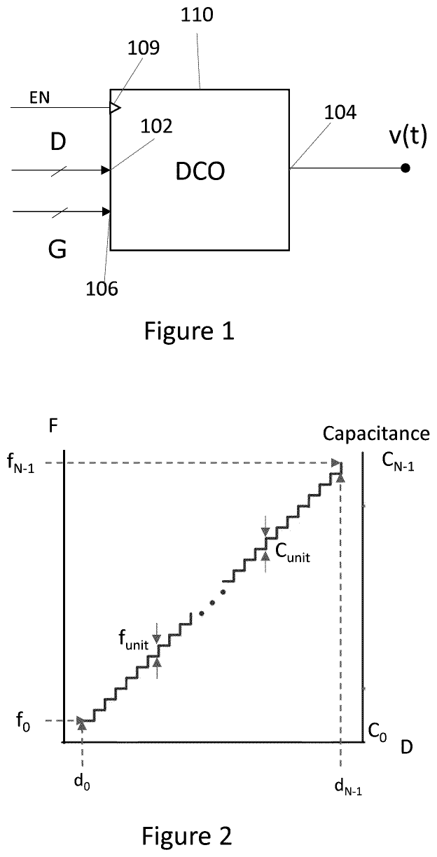

FIG. 1 shows a digitally controlled oscillator (DCO) 110 according to an example of the present disclosure. The DCO 110 has a frequency control input 102 and an analog output 104. The DCO 110 is configured to receive a digital frequency control signal D at the input 102. The digital frequency control signal D can be any one of a plurality of N discrete frequency control values or codes d₀ to d_{N-1}. In other words, the DCO 110 can receive any frequency control value dₙ, where the index n is an integer ranging from 0<n<N−1. Each frequency control value dₙ is indicative of a respective frequency fₙ.

The DCO 110 is configured to generate an output signal v(t) at the output 104, based on the frequency control signal D. The DCO 110 generates the output signal v(t) at an instantaneous frequency F corresponding to (or proportional to) the value of the frequency control signal D. In particular, the DCO 110 generates the output signal v(t) at the frequency fₙ corresponding to the value dₙ of the frequency control signal D. As such, the DCO 110 is able to generate the output signal v(t) at any one of a plurality of N unique instantaneous frequencies f₀ to f_{N-1}.

The output signal v(t) preferably has a sinusoidal waveform. However, it will be appreciated that the output signal v(t) may have any type of periodic waveform (e.g., square wave, triangle wave, sawtooth wave etc.). The output signal v(t) may be suitable for supplying power to a load.

Reference is made to FIG. 2, which further illustrates the mapping between the possible frequency control values d₀ to d_{N-1}, and the corresponding frequencies f₀ to f_{N-1}. The x-axis shows the possible values d₀ to d_{N-1} and the left y-axis shows the corresponding frequencies f₀ to f_{N-1}. As shown, each unique value dₙ will cause the DCO 110 to generate the output signal v(t) at a respective unique instantaneous frequency fₙ. As the value dₙ increases, the fₙ increases in increments of a unit frequency fᵤₙᵢₜ. As such, increasing or incrementing the value of the frequency control signal D will cause an increase in the instantaneous frequency F of the output signal v(t). Decreasing or decrementing the frequency control signal D will cause a decrease in the instantaneous frequency F. The DCO 110 therefore has a nominal output frequency range of f₀ to f_{N-1}.

Optionally, the DCO 110 has an offset control input 106. The offset control input 106 is configured to receive an offset control signal G. The DCO 110 is further configured to generate the output signal v(t) based on the offset control signal G. In particular, the DCO 110 applies a frequency offset to the output signal v(t) based on the offset control signal G.

The offset control signal G may have any one of a plurality of M discrete offset control values g₀ to g_{M-1}. In other words, the offset control signal G may have a value gₘ, where the index m is an integer ranging from 0≤m≤M−1. Each value gₘ is indicative of a respective frequency offset amount δfₘ. The DCO 110 applies a frequency offset δfₘ to the output signal v(t) corresponding to (or proportional to) the value gₘ of the offset control signal G. As such, the DCO 110 is able to apply any one of a plurality of M offset amounts δf₀ to δf_{M-1} to the output signal v(t). The values g₀ to g_{M-1} may be indicative of a combination of negative and positive offset amounts. For example, the value g₀ may be indicative of a negative-most offset amount δf₀. The value g_{M-1} may be indicative of a positive-most offset amount δf_{M-1}. A middle value g_{|(M-1)/}2| may be indicative of an offset value of 0. The instantaneous frequency F at a given time will be F=fₙ+δfₘ, where fₙ is the frequency corresponding to the current value dₙ of the frequency control signal D, and δfₘ is the frequency offset amount corresponding to the current value gₘ of the offset control signal G.

Optionally, the DCO 110 has an enable terminal 109. The enable terminal 109 is configured to receive an enable signal EN. The enable signal EN can be used to turn the DCO 110 off and on. The enable signal EN can have a first state (e.g. “0” or “low”), and a second state (e.g. “1” or “high”). When the enable signal EN is in the second state, the DCO 110 operates in an on-state. In the on-state, the DCO 110 generates and outputs the output signal v(t). When the enable signal EN is in the first state, the DCO 110 operates in an off-state. In the off-state, the DCO 110 does not output the output signal v(t).

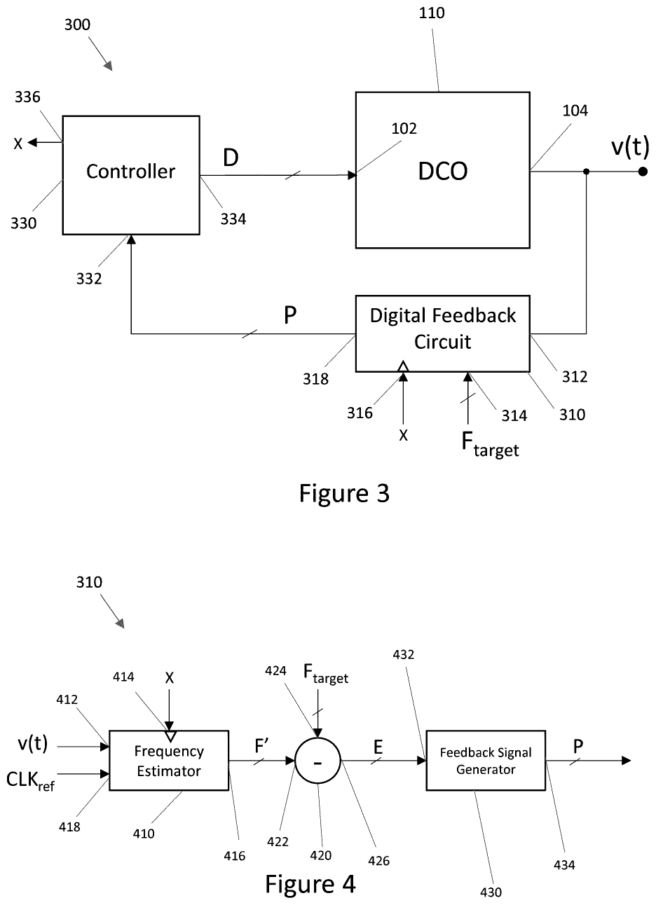

FIG. 3 shows an oscillator circuit 300 according to an example of the present disclosure. As described below, the oscillator circuit 300 is able to maintain the instantaneous frequency F of the output signal v(t) substantially at, or at least within a tolerance range of, a target frequency F_{target}.

The oscillator circuit 300 includes the DCO 110, a digital feedback circuit 310, and a controller 330. The controller 330 has a digital input 332 where it receives a digital feedback signal P. The digital feedback signal P is received from a digital output 318 of the digital feedback circuit 310. The digital feedback signal P is indicative of a desired frequency control value. In particular, the feedback signal P may be any one of a plurality of N discrete values p₀ to P_{N-1}. In other words, the feedback signal P may have a value pₙ, where the index n is an integer ranging from 0≤n≤N−1. Each value pₙ is indicative of a respective frequency control value dₙ.

The controller 330 is configured to generate the frequency control signal D based on the feedback signal P. In particular, the controller 330 sets the value of the frequency control signal D to the desired frequency control value indicated by the feedback signal P. For example, if the current value of the feedback signal P is pₙ, the controller 330 sets the value of the frequency control signal D to the corresponding frequency control value dₙ.

The controller 330 has a digital output 334. The controller 330 is configured to output the digital frequency control signal D at the output 334. The output 334 is coupled to the frequency control input 102 of the DCO 110. As such, the DCO 110 will generate the output signal v(t) at the frequency corresponding to the value of the frequency control signal D.

The digital feedback circuit 310 has an analog input 312 where it receives the output signal v(t) at the analog input 312. The digital feedback circuit 310 is also configured to receive a target or reference frequency value F_{target} at a frequency reference input 314, and a command signal X at a control input 316. The target frequency value F_{target} may be represented by a digital code. The command signal X is received from a command output 336 of the controller 330. The command signal X may be, for example, a pulse. The command signal X may be considered as a control instruction from the controller 330. The controller 330 may discontinuously or aperiodically provide the command signal X to the digital feedback circuit 310.

The digital feedback circuit 310 is configured to perform an update cycle in response to receiving the command signal X from the controller 336. In the update cycle, the digital feedback circuit 310 updates the value of the digital feedback signal P. In particular, the digital feedback circuit 310 adjusts or updates the digital feedback signal P in such a way to reduce or minimise an error between the instantaneous frequency F of the output signal v(t) and the target frequency value F_{target}. When the feedback signal P is adjusted, the controller 330 will adjust the frequency control signal D accordingly, which will cause the instantaneous frequency F of the output signal v(t) to be adjusted. For example, increasing the value of the feedback signal P will cause a corresponding increase in the instantaneous frequency F of the output signal v(t). Decreasing the value of the feedback signal P will cause a corresponding decrease in the instantaneous frequency F of the output signal v(t). As such, each time the controller 330 outputs the command signal X, the error between the instantaneous frequency of the output signal v(t) and the target frequency F_{target} will be reduced or minimised. The controller 330 may output the command signal X periodically (e.g. at regularly intervals), or at irregular intervals. In any case, over time, the oscillator circuit 300 is able to maintain the instantaneous frequency F of the output signal v(t) substantially at, or within a tolerance range of, the target frequency F_{target}.

FIG. 4 shows the digital feedback circuit 310 in more detail. The feedback circuit 310 includes a frequency estimator 410 (also referred to as a frequency measurement circuit), a digital subtractor 420, and a feedback signal generator 430. The frequency estimator 410 receives the output signal v(t) of the oscillator at an analog input 412. The frequency estimator 410 is also configured to receive the command signal X at a control input 414. The frequency estimator 410 is configured to estimate or measure the instantaneous frequency of the output signal v(t) in response to receiving the command signal X. In particular, the frequency estimator 410 may estimate the frequency within a time window initiated by the receipt of the command signal X. The frequency estimator 410 may estimate the instantaneous frequency relative to a reference clock CLK_{ref} received at a reference clock input 418 of the frequency estimator. The frequency estimator 410 is configured to output the frequency estimate F′ at an output 416 of the frequency estimator 416. The frequency estimate F′ may be represented by a digital signal.

The digital subtractor 420 receives the frequency estimate F′ at a first input 422, and the target frequency value F_{target} at a second input 424. The digital subtractor 420 is configured to determine an error E between the frequency estimate F′ and the target frequency value F_{target}. In particular, the digital subtractor 420 calculates the error as a difference between the frequency estimate F′ and the target frequency F_{target}, where E=F′-F_{target}. As such, if the error value E is positive, then it indicates that the instantaneous frequency F is greater than the target value F_{target}. If the error value E is negative, then it indicates that the instantaneous frequency F is less than the target value F_{target}. If the absolute value of the error value E is below a (non-zero) threshold e_{T}, then this may indicate that the instantaneous frequency F is substantially at, or within a tolerance range of, the target frequency F_{target}. The subtractor 420 outputs the error value E at an output 426 of the subtractor 420. The error value E may be represented by a digital signal.

The feedback signal generator 430 receives the error value E at an input 432. The feedback signal generator 430 is configured to adjust or update the feedback signal P based on the error value E. The feedback signal generator 430 adjusts the feedback signal P in such a way to reduce or minimise the error between the instantaneous frequency F and the target value F_{target}. In particular, the feedback signal generator 430 may adjust the feedback signal P based on the polarity of the error value E. For example, if the error E is positive, then this may indicate that the frequency F of the output signal v(t) is above the target frequency F_{target}. In this case, the feedback signal generator 430 may decrease or decrement the value of the feedback signal P (e.g. from pₙ to pₙ₋₁). This will cause a corresponding reduction in the value of the frequency control signal D outputted by the controller 330 (e.g. from dₙ to dₙ₋₁). In turn, there will therefore be a corresponding reduction in the frequency F of the output signal v(t) (e.g. from fₙ to fₙ₋₁), which will thereby reduce the error. If the error E is negative, then this may indicate that the frequency F of the output signal v(t) is below the target frequency F_{target}. In this case, the feedback signal generator 430 may increase or increment the value of the feedback signal P (e.g. from pₙ to pₙ₊₁). This will cause a corresponding increase in the value of the frequency control signal D outputted by the controller 330 (e.g. from dₙ to dₙ₊₁). In turn, there will therefore be a corresponding increase in the frequency F of the output signal v(t) (e.g. from fₙ to fₙ₊₁), which will thereby reduce the error. In some examples, if the absolute value of the error E is below an error threshold e_{T}, then the feedback signal generator 430 may leave the feedback signal P unchanged as a result of the update cycle. As such, the error threshold er may define a tolerance range about the target frequency F_{target}. Advantageously, this may improve the stability of the feedback signal P. Furthermore, this may also improve the stability of the frequency control signal D, by eliminating limit cycle behaviour (i.e. by eliminating the repetitive toggling of the signal in steady state conditions).

Each time that the digital feedback signal 310 receives the command signal X, the digital feedback circuit 310 will update the feedback signal P as described above. As such, over time, the feedback circuit 310 is able to maintain the frequency F of the output signal v(t) substantially at, or within a tolerance range of, the target frequency F_{target}.

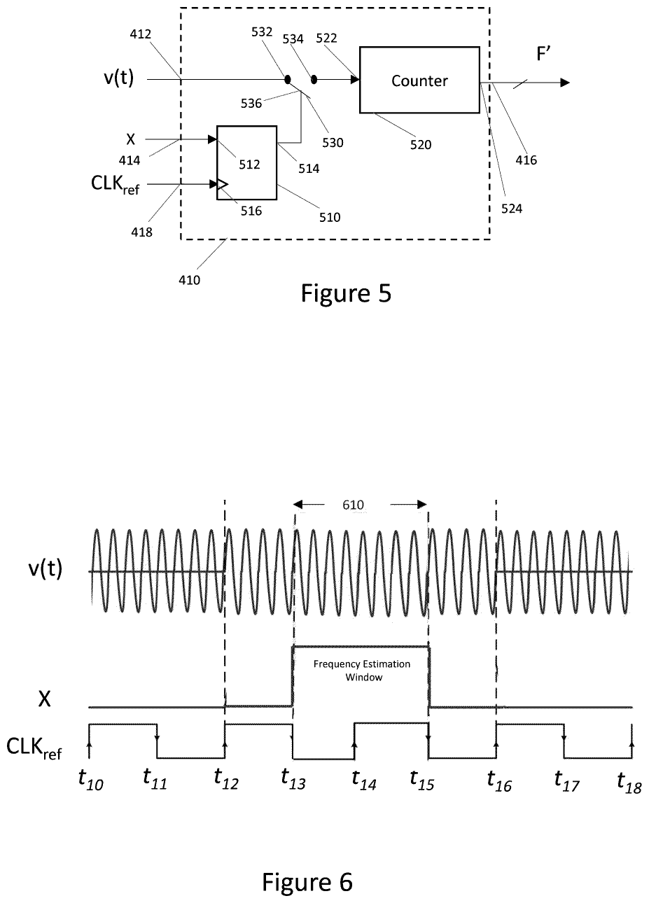

FIG. 5 shows the frequency estimator 410 in more detail. The frequency estimator 410 includes a counter 520, a switch 530, and a switch controller 510. The switch controller 510 is implemented as a D-type flip flop (FF).

The counter 520 is configured to receive the signal v(t) at an input 522 of the counter 520, via the switch 530. In particular, the switch 530 has a first terminal 532 that receives the signal v(t), and a second terminal 534 coupled to the input 522 of the counter 520. The counter 520 will receive the signal v(t) when the switch 530 is closed. The FF 510 is configured to receive the command signal X at a data input 512, and a reference clock CLK_{ref} at a clock input 418. The FF 510 has a data output 514 coupled to a control terminal 536 of the switch 530. The switch 530 is configured to open when the data output 514 is in a first state (e.g. “0” or “low”), and close when the data output 514 is in a second state (e.g. “1” or “high”). In some examples, the switch 530 can be implemented as a logic gate. For example, the switch 530 can be an AND gate, which performs an AND operation between the data output 514 and the signal 412 to produce the signal 522.

The functionality of the frequency estimator 410 shown in FIG. 5 is described in reference to FIG. 6. As shown, the command signal X may comprise a pulse. The data output 514 may initially be low, and therefore the switch 530 may initially be open. The FF 510 receives a rising edge of the pulse at time t13. This causes the data output 514 to go high at the falling edge of the reference clock CLK_{ref}, at time t₁₃. As such, at time t₁₃, the switch 530 is closed. The data output 514 then returns to low at the subsequent falling edge of the reference clock CLK_{ref}, at time t₁₅. As such, at time t₁₅, the switch 530 is again opened. The times t₁₃ to t₁₅ thus define a frequency estimation window 610, which corresponds to a period of the reference clock CLK_{ref}. During the frequency estimation window 610, whilst the switch is closed, the counter 520 counts the number of periods or cycles of the signal v(t). The number of cycles is indicative of the frequency F of the signal v(t) relative to the reference clock CLK_{ref}. Then, the counter 520 outputs the final counter value at an output 524 of the counter 520 as the frequency estimate F′. Therefore, the frequency estimate F′ may correspond to a number of cycles of the signal v(t) that occur within a period (or any defined number of periods) of the reference clock CLK_{ref}. Accordingly, in order to ensure proper comparison between the frequency estimate F′ and the target frequency value F_{target}, the target frequency value F_{target} may be represented by a target number of cycles for the signal v(t) within the period (or any defined number of periods) of the reference clock CLK_{ref}.

It will be appreciated that FIG. 5 shows one possible implementation of the frequency estimator 410, and other alternative implementations are envisaged. For example, the frequency estimator 410 may employ various other frequency estimation techniques, including use of phase interpolation, a calibrated TDC, and/or a calibrated ring oscillator.

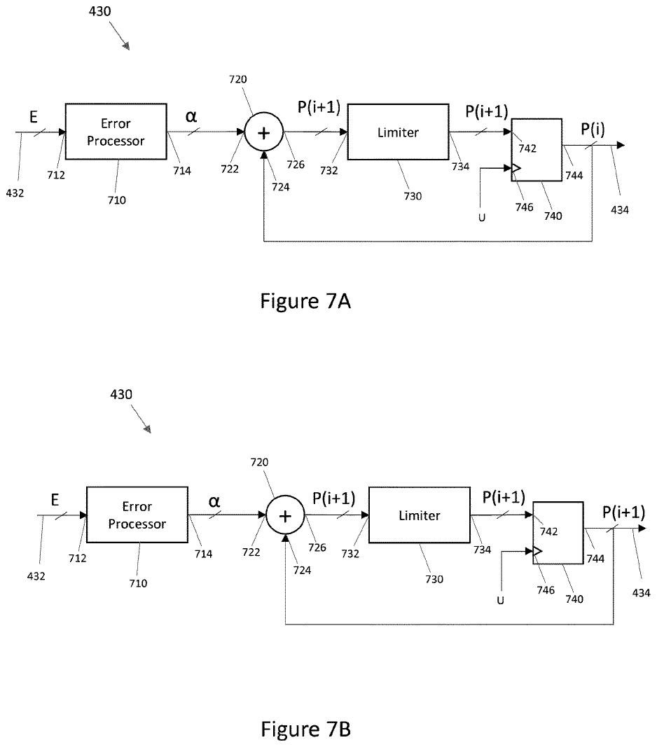

FIG. 7A shows the feedback signal generator 430 in more detail. The feedback signal generator 430 includes an error processor 710, a digital adder 720, a limiter 730 and a register 740. The register 740 is shown as being implemented as a flip flop (FF).

The error processor 710 receives the error value E at an input 712. The error processor 710 is configured to generate an adjustment value a based on the error value E. The adjustment value a indicates an amount by which the feedback signal P is to be adjusted. The error processor 710 may generate the adjustment value a based on the polarity of the error value E.

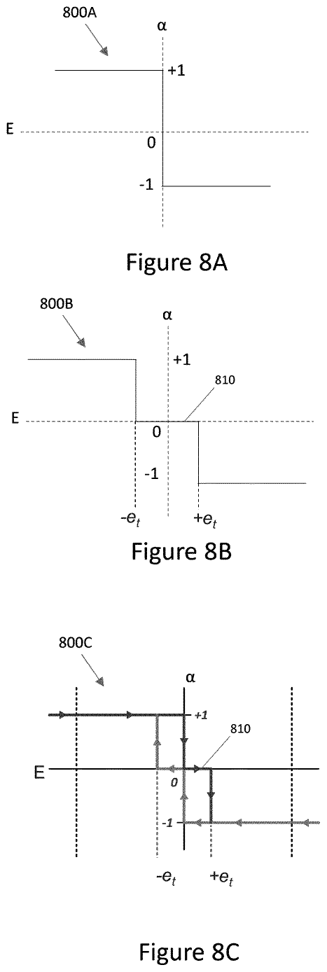

FIG. 8A shows an example transfer function 800A of the error processor 710. The transfer function 800A shows the error value E on the x-axis, and the resulting adjustment value a on the y-axis. As shown, if the error value E is positive (>0), then the error processor 710 may generate an adjustment value of α=−1. In turn, this will cause the value of the feedback signal P to be decremented or decreased (e.g. from pₙ to pₙ₋₁), to decrease the frequency control signal D and the frequency F of the output signal v(t) as described above. If the error value E is negative (<0), then the error processor 710 may generate an adjustment value of α=+1. In turn, this will cause the value of the feedback signal P to be incremented or increased (e.g. from pₙ to pₙ₊₁), to increase the frequency control signal D and the frequency F of the output signal v(t) as described above. If the error value E is approximately 0, then the error processor 710 may generate an adjustment value of α=0, so that the feedback signal P remains unchanged as a result of the update cycle.

FIG. 8B shows another example transfer function 800B of the error processor 710. The transfer function 800B is similar to that of 800A. However, as shown, the transfer function 800B includes a deadband 810 between the (non-zero) error thresholds −e_{T} and +e_{T}. Accordingly, if the absolute error value |E| is less than an error threshold e_{T}, the error processor 710 may generate an adjustment value of α=0, so that the feedback signal P remains unchanged as a result of the update cycle. In other words, the error processor 710 may generate an adjustment value of α=0 if the error value E is in between a lower error threshold −e_{T} and an upper error threshold +e_{T}. Advantageously, the transfer function 800B may provide the adjustment value α with improved stability. The absolute values of −e_{T} and +e_{T} may be the same or different.

FIG. 8C shows another example transfer function 800C of the error processor 710. The transfer function 800C is similar to that of 800B. However, as shown, the transfer function 800C exhibits a hysteresis behaviour in the deadband region 810. In particular, the error processor 710 may generate the adjustment value a further based on the previous error value from a previous update cycle. If the previous error value is less than the current error value E, then this may indicate that the error has changed in a positive direction. In this case, the error processor 710 may operate in a first mode. In the first mode, the transfer function 800C only applies the upper error threshold +eₜ, and not the negative error threshold −e_{T}. In particular, if the error value E is negative (<0), the error processor 710 generates an adjustment value α=+1. If the error value E is between 0 and +e_{T}, the error processor 710 generates an adjustment value α=0. If the error value E is above +e_{T}, the error processor 710 generates an adjustment value α=−1. As such, in the first mode, the error processor 710 uses a positive-side deadband between 0 and e_{T}. If the previous error value is greater than than the current error value E, then this may indicate that the error has changed in a negative direction. In this case, the error processor 710 may operate in a second mode. In the second mode, the transfer function 800C applies the negative error threshold −e_{T} and not the positive error threshold +e_{T}. In particular, if the error value E is positive (>0), the error processor 710 generates an adjustment value α=−1. If the error value E is between 0 and −e_{T}, the error processor 710 generates an adjustment value α=0. If the error value E is below −e_{T}, the error processor 710 generates an adjustment value α=+1. As such, in the first mode, the error processor 710 uses a negative-side deadband between 0 and −e_{T}. Advantageously, a bang-bang detector with hysteresis may generate the adjustment signal a with further improved stability. The absolute values of −e_{T} and +e_{T} may be the same or different.

Reference is made back to FIG. 7A. The adder 720 receives the adjustment value α at a first input 722, and the current feedback signal P at a second input 724. The current feedback signal P may be denoted P(i). The adder 720 is configured to generate an updated or adjusted feedback signal by adding the adjustment value a to the value of the current feedback signal P(i). The updated feedback signal may be denoted P(i+1). For example, if the current value of the feedback signal is P(i)=pₙ, then the updated feedback signal may have a value P(i+1)=pₙ₊ₐ. The adder 720 is configured to output the updated feedback signal P(i+1) at an output 726.

The limiter 730 is configured to receive the updated feedback signal P(i+1) at an input 732. The limiter 730 is configured to limit the value of the feedback signal P(i+1) to the range of values p₀ to p_{N-1}. In particular, the limiter 730 checks whether the value of the feedback signal P(i+1). The value of the feedback signal P(i+1) may be invalid if it has been incremented above p_{N-1} or decremented below p₀. If the limiter 730 determines that the value of the feedback signal P(i+1) exceeds p_{N-1}, then the limiter 730 will limit the feedback signal to the value p_{N-1}. If the limiter 730 determines that the value of the feedback signal P(i+1) falls below p₀, then the limiter 730 will set the feedback signal to the value p₀. The limiter 730 then outputs the updated (and limited) feedback signal P(i+1) at an output 734.

The register 740 receives the updated feedback signal P(i+1) at an input 742. The register 740 includes a control input 746 configured to receive an update signal U. The update signal U may have a first state (e.g. “0” or “low”) and a second state (e.g. “1” or “high”). When the update signal U is in the first state, the register 740 holds the updated feedback signal P(i+1) at the input 742, and holds the current feedback signal P(i) at an output 744. Then, when the update signal is in the second state, the register 740 provides the feedback signal P(i+1) to the output 744, as shown in FIG. 7B. The updated feedback signal P(i+1) will then be outputted by the digital feedback circuit 310. The register 740 may receive the update signal U, e.g. from the controller 330, once the updated feedback signal P(i+1) is ready at the input 742. In general, the controller 330 may provide the update signal U at a different time to providing the command signal X. In particular, the controller 330 may provide the update signal U at a predetermined or scheduled amount of time following the command signal X, e.g. to allow enough time for the updated feedback signal to be generated.

In some examples, the limiter 730 may be optional, and the register 740 may receive the updated feedback signal P(i+1) directly from the adder 720. Additionally or alternatively, in some examples, the register 740 may be optional. Instead, the updated feedback signal P(i+1) may be directly provided to the output of the feedback circuit 310 after being outputted by the limiter 734 (or by the adder 720)

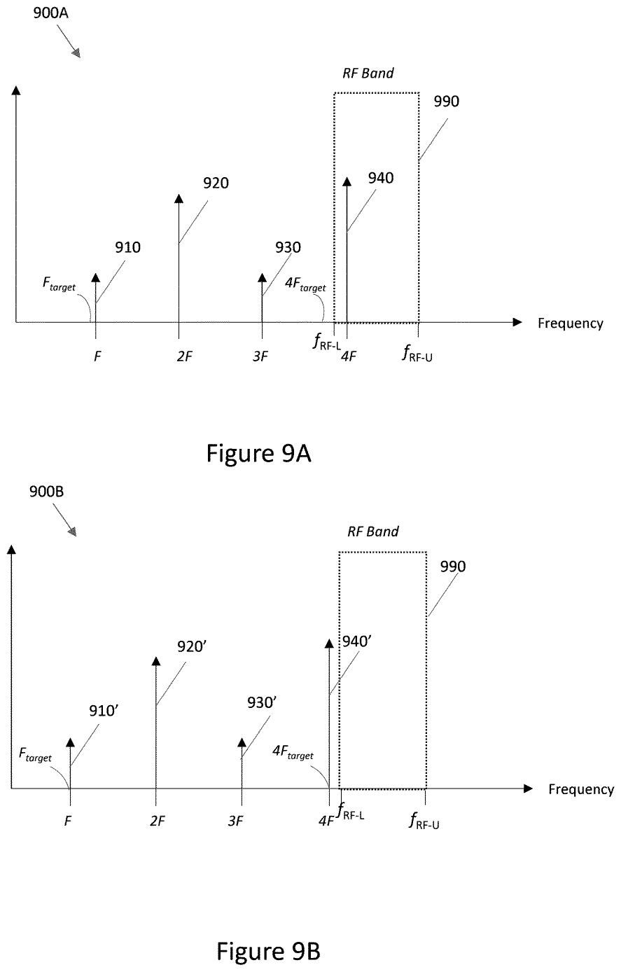

Reference is made to FIG. 9A, which shows an initial electromagnetic emissions spectrum 900A of the oscillator output signal v(t) generated by the circuit 300. As shown, the emissions spectrum 900A includes emissions peaks 910, 920, 930, 940. The emissions peak 910 is the result of the (fundamental) frequency F of the output signal v(t). The emissions peaks 920, 930, 940 are the results of second, third and fourth harmonics of the output signal v(t), respectively. Although not shown, the emissions may include additional emissions peaks caused by further harmonics of the output signal v(t). Even order harmonics may result in larger or more powerful emissions peaks, as a result of common mode currents in the circuit 300 (e.g. in the DCO 110).

In some examples, the oscillator circuit 300 may include a radio-frequency (RF) transceiver (or may otherwise be in close proximity to a RF transceiver). The RF transceiver may operate across an RF frequency band 990 shown in FIG. 9A, between a lower RF frequency f_{RF-L} and an upper RF frequency f_{RF-U}. Although the fundamental frequency range of the DCO 110 is well below the RF band 990, harmonic emissions of the signal v(t) may still overlap with the RF frequency band 990. For example, as shown in FIG. 9A, the emissions peak 940 may enter the RF frequency band 990. This may cause interference with the wireless signals transmitted or received by the RF transceiver.

One option to reduce interference may be to add shielding to the circuit 300. However, this may add significant cost to the circuit. Moreover, if parts of the circuit 300 are galvanically isolated, then the shielding may reduce the effectiveness of the galvanic isolation.

In view of the above, it may be desirable to maintain the frequency F of the signal v(t) at a target frequency F_{target}. The target frequency F_{target} may be selected so that the 4′th harmonic emission 940 is not within the RF band 990. In particular, the target frequency F_{target} can be determined to meet the condition k*F_{target}<F_{RF-L}, where in this case k=4.

One option is to identify an instantaneous frequency fₙ of the set of frequencies f₀ to f_{N-1} which corresponds to (or is otherwise closest to) F_{target}. The controller 330 could then fix the digital control signal D at the value dₙ. However, this may only temporarily keep the frequency F of the output signal v(t) at the target frequency. In particular, the mapping between the frequency control values d₀ to d_{N-1} and the resulting frequencies f₀ to f_{N-1} may change over time, e.g. due to PVT drift, load pull and/or aging effects within the circuit 100. Consequently, the frequency fₙ generated by the DCO 110 in response to the value dₙ may eventually drift from the target frequency F_{target}. As such, over time, the frequency of the signal v(t) may drift in such a way that the fourth harmonic emission 940 re-enters the RF band 990.

Using the circuit 300, the frequency F of the signal v(t) can be maintained substantially at, or within a tolerance range of, the target frequency F_{target}. In particular, the controller 330 can provide the command signal X to the digital feedback circuit 310 on a regular or irregular basis. Each time the digital feedback circuit 310 receives the command signal X, the digital feedback circuit 310 will perform an update cycle as described above, in order to reduce the error between the frequency F of the output signal v(t) and the target frequency F_{target}. Over time, this will ensure that the frequency F of the signal v(t) stays at the target frequency F_{target}.

FIG. 9B shows an emissions spectrum 900B after running one or more update cycles. As shown, the frequency F of the signal v(t) may be at the target frequency F_{target}. Accordingly, fourth harmonic emissions 940′ are at the fourth harmonic of the target frequency 4F_{target}, which falls outside of the RF band 990. The controller 330 can continue to output the command signal X to run update cycles, in order to maintain F at F_{target}.

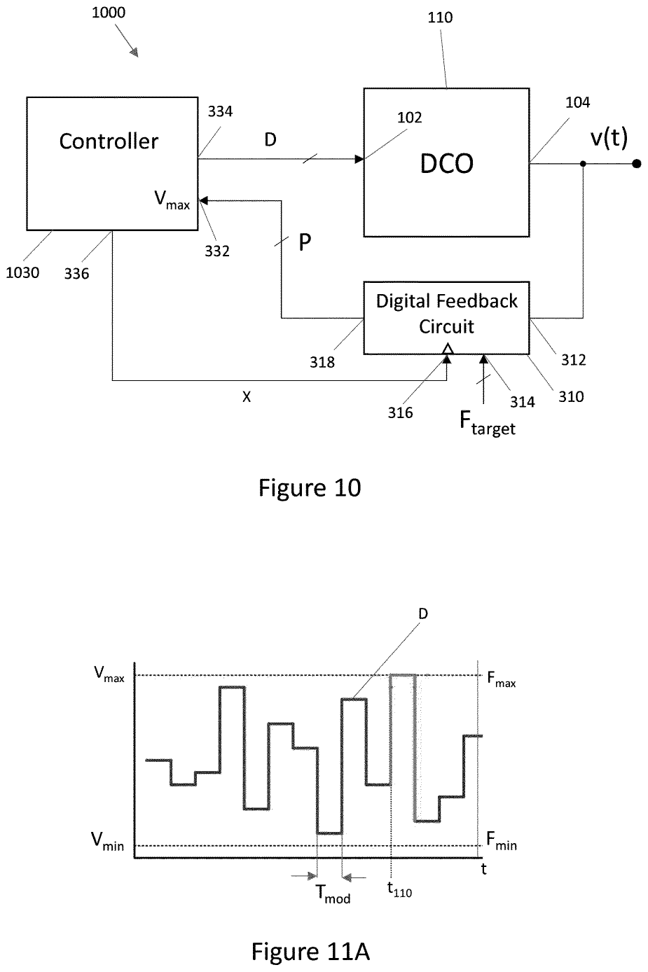

FIG. 10 shows an oscillator circuit 1000 according to another example of the present disclosure. The oscillator circuit 1000 differs from the oscillator circuit 300 as described below. It will be appreciated that the circuit 1000 may otherwise be similar to the oscillator circuit 300, at least by virtue of the like reference signs.

As described below, in the oscillator circuit 1000, the signal v(t) is generated in accordance with a spread spectrum frequency modulation scheme. In particular, the instantaneous frequency of the signal v(t) is modulated across a range of discrete frequencies. The oscillator circuit 1000 is able to maintain the maximum instantaneous frequency of the signal v(t) substantially at, or within a tolerance range of, the target frequency F_{target}.

The oscillator circuit 1000 includes a controller 1030. The controller 1030 is similar to the controller 330, but differs as follows. The controller 1030 stores a parameter Vₘₐₓ corresponding to a maximum frequency control value. The controller 1030 also stores a parameter Vₘᵢₙ corresponding to a minimum frequency control value. For example, Vₘₐₓ may be initialised to the highest possible value d_{N-1}, and Vₘᵢₙ may be initialised to the lowest possible value d₀.

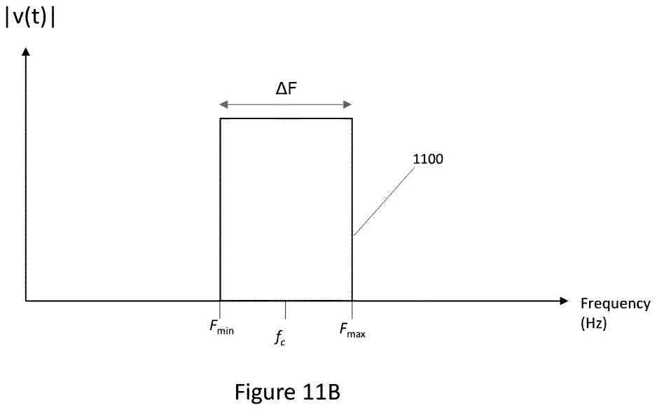

The controller 1030 generates the frequency control signal D based on the maximum frequency control value Vₘₐₓ and the minimum frequency control value Vₘᵢₙ. Reference is made to FIG. 11A, which shows the value of the frequency control signal D (left y-axis) over time (x-axis). As shown, the frequency control signal D corresponds to a pseudo-random sequence of frequency control values. The sequence of values is provided at a frequency modulation rate F_{mod}. In other words, the value of the frequency control signal D changes every T_{mod}=1/F_{mod} seconds in accordance with the sequence. The sequence is generated from each of the frequency control values in between, and including, the minimum frequency control value Vₘᵢₙ and the maximum frequency control value Vₘₐₓ. For example, initially, the sequence may be generated using each of the frequency control values Vₘᵢₙ=d₀ to Vₘₐₓ=d_{N-1}. It will be appreciated that in some examples, the frequency control signal D is not a pseudo-random sequence, but may instead be a cyclic pattern of frequency control values (e.g. in a triangle pattern that repeatedly increases the values in ascending order to Vₘₐₓ, then decreases the values in descending order to Vₘᵢₙ, or e.g. in a Hershey-kiss pattern).

As a result of the frequency control signal D, the DCO 110 receives the sequence of frequency control values at the frequency control input 102. Consequently, the instantaneous frequency of the signal v(t) will be modulated at the modulation rate F_{mod}. In particular, the instantaneous frequency of v(t) will change every T_{mod} seconds in response to the sequence of frequency control values received at the input 102. As indicated in FIG. 11A (right y-axis), the maximum instantaneous frequency Fₘₐₓ of the signal v(t) will be the frequency corresponding to the maximum frequency control value Vₘₐₓ. The minimum instantaneous frequency Fₘᵢₙ of the signal v(t) will be the frequency corresponding to the minimum frequency control value Vₘᵢₙ. As such, as shown in FIG. 11B, the signal v(t) will have a frequency range Fₘᵢₙ to Fₘₐₓ that is dependent on the value range Vₘᵢₙ to Vₘₐₓ of the frequency control signal D. The signal v(t) will have a bandwidth ΔF=Fₘₐₓ−Fₘᵢₙ centred on a centre frequency f_{c}. Fₘₐₓ may be considered as an upper edge of the bandwidth ΔF and Fₘᵢₙ may be considered as a lower edge of the bandwidth ΔF. Initially where Vₘᵢₙ=d₀ to Vₘₐₓ=d_{N-1}, the maximum instantaneous frequency will be Fₘₐₓ=f_{N-1}, and the minimum instantaneous frequency will be Fₘᵢₙ=f₀. Therefore, signal v(t) will have an initial frequency range of Fₘᵢₙ=f₀ to Fₘₐₓ=f_{N-1}. Advantageously, modulating the frequency of the output signal v(t) across the range Fₘᵢₙ to Fₘₐₓ will result in a reduction of the average power/magnitude of the emissions peak 1100 corresponding to the fundamental frequency of v(t). This may enable the circuit to more meet requirements of industrial emissions standards.

The controller 1030 interprets the value of the feedback signal P as being indicative of the maximum frequency control value Vₘₐₓ. In particular, as described above, the value of the feedback signal P is indicative of a frequency control value. The controller 1030 sets the maximum frequency control value Vₘₐₓ to the frequency control value indicated in the value of the feedback signal P. For example, the feedback signal may have a value pᵥ, where pᵥ is any of the values p₀ to P_{N-1}. The value pᵥ is indicative of a corresponding frequency control value dᵥ. The controller 1030 then interprets the frequency control value dᵥ as the maximum frequency control value. In particular, the controller 1030 sets the maximum frequency control value Vₘₐₓ to dᵥ. As such, each time the value of the feedback signal P is updated to a new value (e.g. pᵥ+1), the controller 1030 correspondingly updates the maximum frequency control value Vₘₐₓ (e.g. to dᵥ+1).

The controller 1030 is configured to output the command signal X when the current value of the frequency control signal D (i.e. the current frequency control value in the sequence) is the maximum frequency control value Vₘₐₓ. In other words, the controller 1030 may output the command signal X when it outputs the maximum frequency control value Vₘₐₓ at the frequency control output 334. For example, with reference with FIG. 11A, the controller 1030 may output the command signal X at a time t110. This will cause the digital feedback circuit 310 to perform the update cycle whilst v(t) is being generated by the DCO 110 at the maximum instantaneous frequency Fₘₐₓ. As such, the digital feedback circuit 310 will adjust or update the digital feedback signal P in such a way to reduce or minimise an error between the maximum instantaneous frequency Fₘₐₓ of the output signal v(t), and the target frequency value F_{target}. For example, as described previously, the feedback circuit 310 may measure the instantaneous frequency Fₘₐₓ, determine an error between the measured frequency and the frequency target F_{target}, and then adjust or update the feedback signal P based on the error. The feedback circuit 310 may function as described in connection with the previously described examples, and therefore the detailed functioning of the feedback circuit 310 is not repeated here.

When the feedback signal P is adjusted, the controller 1030 will adjust the value of the parameter Vₘₐₓ accordingly. As described above, the frequency control signal D is generated using only the frequency control values Vₘᵢₙ to Vₘₐₓ. Therefore, in turn, an adjustment to the maximum frequency control value Vₘₐₓ will cause a corresponding adjustment to the maximum instantaneous frequency Fₘₐₓ of the output signal v(t). This will cause a change in the bandwidth ΔF and centre frequency f_{c} of the signal v(t). For example, if the feedback signal P is incremented (e.g. from pᵥ to pᵥ₊₁), the controller 1030 will accordingly increment the maximum frequency control value Vₘₐₓ (e.g. from dᵥ to dᵥ+1). The maximum frequency Fₘₐₓ of the signal v(t) will therefore increase (e.g. from fᵥ to fᵥ₊₁), which effectively increases the bandwidth ΔF and centre frequency f_{c} of the signal v(t). If the feedback signal P is decremented (e.g. from pᵥ to pᵥ₋₁), the controller 1030 will accordingly decrement the maximum frequency control value Vₘₐₓ (e.g. from dᵥ to dᵥ₋₁). The maximum frequency Fₘₐₓ of the signal v(t) will therefore decrease (e.g. from fᵥ to fᵥ₋₁), which effectively decreases the bandwidth ΔF and centre frequency f_{c} of the signal v(t). If the feedback signal P is left unchanged (e.g. because the error is within a tolerance range), the controller 1030 will leave the maximum frequency control value Vₘₐₓ unchanged. The bandwidth and centre frequency of the signal v(t) may therefore remain unchanged.

As such, each time the controller 1030 outputs the command signal X, the error between the maximum instantaneous frequency Fₘₐₓ of the signal v(t) and the target frequency F_{target} will be reduced or minimised. The controller 1030 may output the command signal X each time (or at least some of the times) the frequency control signal D is at the maximum value Vₘₐₓ. Over time, the oscillator circuit 1000 is able to maintain the maximum instantaneous frequency Fₘₐₓ of the output signal v(t) substantially at, or within a tolerance range of, the target frequency F_{target}.

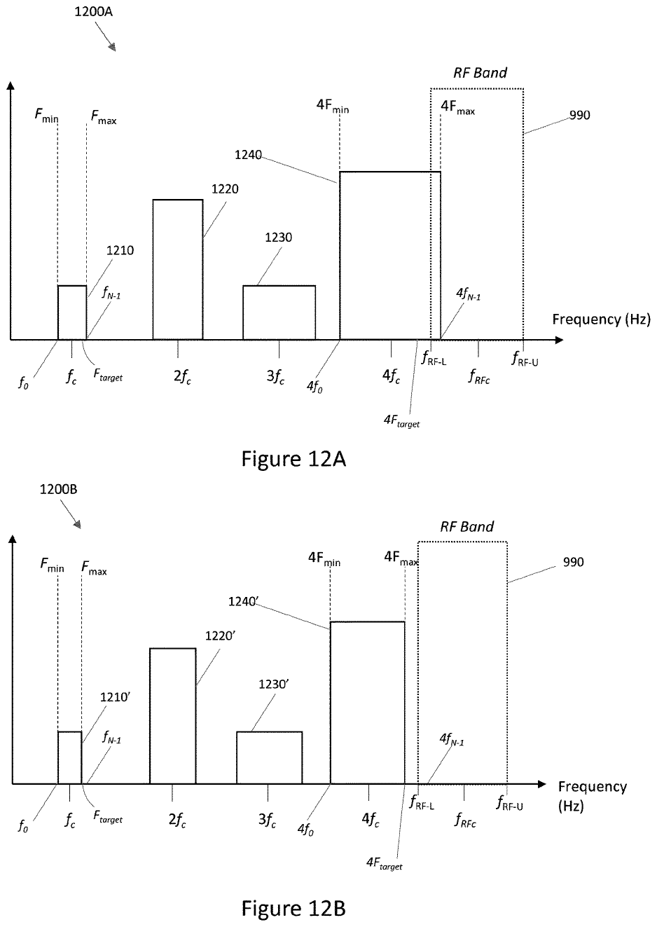

Reference is made to FIG. 12A which shows an initial electromagnetic emissions spectrum 1200A of the oscillator output signal v(t) generated by the circuit 1000. As shown, the emissions spectrum 1200A includes emissions bands 1210, 1220, 1230, 1240. The emissions band 1210 is the result of the (fundamental) frequency F of the output signal v(t) being modulated across the frequency range Fₘᵢₙ to Fₘₐₓ. The emissions bands 1220, 1230, 1240 are the results of second, third and fourth harmonics of the output signal v(t), respectively. Although not shown, the emissions may include additional emissions bands caused by further harmonics of the output signal v(t). Even order harmonics may result in larger or more powerful (i.e. higher magnitude) emissions bands, as a result of common mode currents in the circuit 1000 (e.g. in the DCO 110).

As shown in FIG. 12A, the emissions band 1240 overlaps with the RF band 990. The emissions band 1240 has a bandwidth 4ΔF with an upper frequency 4Fₘₐₓ and a lower frequency 4Fₘᵢₙ, centred on the centre frequency 4f_{c}. The upper frequency 4Fₘₐₓ is initially greater than the lower frequency f_{RF-L} of the RF band 990. This means that over time, the signal v(t) will be modulated to instantaneous frequencies that are within the RF band 990. As described previously, this may cause interference with the wireless signals transmitted or received by the RF transceiver.

The target frequency F_{target} may be selected to meet the condition k*F_{target}<f_{RF-L}, where in this case k=4. Using the circuit 1000, the maximum frequency Fₘₐₓ of the signal v(t) can be maintained substantially at, or within a tolerance range of, the target frequency F_{target}. In particular, the controller 1030 can provide the command signal X to the digital feedback circuit 310 each time (or at least some of the times) that the DCO 110 is operating at the frequency Fₘₐₓ. Each time the digital feedback circuit 310 receives the command signal X, the digital feedback circuit 310 will perform an update cycle as described above, in order to reduce the error between the frequency Fₘₐₓ of the output signal v(t) and the target frequency F_{target}. Over time, this will ensure that the frequency Fₘₐₓ of the signal v(t) stays at the target frequency F_{target}.

FIG. 12B shows an emissions spectrum 1200B after running one or more update cycles. As shown, the maximum frequency Fₘₐₓ of the signal v(t) may be at the target frequency F_{target}. Accordingly, the frequency range of the fundamental harmonic is adapted to Fₘᵢₙ to F_{target}. The frequency range of the fourth harmonic emissions 1240′ is now between 4Fₘᵢₙ to 4F_{target}, where 4F_{target}<f_{RF-L}. The controller 1030 can continue to output the command signal X to run update cycles when the DCO 110 is operating at Fₘₐₓ, in order to maintain Fₘₐₓ at F_{target}.

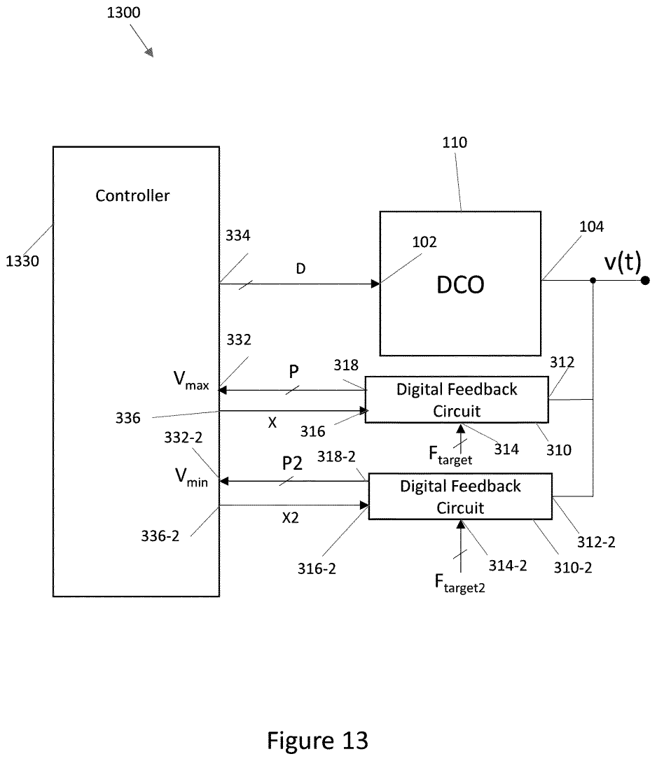

FIG. 13 shows an oscillator circuit 1300 according to another example of the present disclosure. The oscillator circuit 1300 is similar to the oscillator circuit 1000 (at least by virtue of the like-reference signs), with the differences described below. In particular, as described below, the oscillator circuit 1300 is able to simultaneously maintain the maximum frequency Fₘₐₓ of the signal v(t) at the target frequency F_{target}, and the minimum frequency Fₘᵢₙ at a second target frequency F_{target2}.

The oscillator circuit 1300 includes a second digital feedback circuit 310-2. The digital feedback circuit 310-2 has an analog input 312-2 where it receives the output signal v(t). The digital feedback circuit 310-2 is also configured to receive a second target or reference frequency value F_{target2} at a frequency reference input 314-2, and a second command signal X2 at a control input 316-2. The digital feedback circuit 310-2 is also configured to output a second feedback signal P2 at an output 318-2. The digital feedback circuit 310-2 functions similarly to the digital feedback circuit 310, and so is not described in detail.

Moreover, the signals P2, X2 and F_{target2} may be characterised similarly to the corresponding signals received/outputted by the digital feedback circuit 310, and so are not described in detail. The first command signal X may be considered as a first control instruction from the controller, and the second command signal X2 may be considered as a second control instruction from the controller.

The oscillator circuit 1300 includes a controller 1330 which is similar to the controller 1030. However, the controller 1330 further includes a second digital feedback input 332-2 and a second command output 336-2. The controller 1030 receives the second digital feedback signal P2 at the input 332-2. The controller 1030 is also configured to provide the second command signal X2 to the digital feedback circuit 310-2 from the second command output 336-2.

The controller 1330 interprets the value of the feedback signal P2 as being indicative of the minimum frequency control value Vₘᵢₙ. In particular, as described above, the value of the feedback signal P2 is indicative of a frequency control value. The controller 1330 sets the minimum frequency control value Vₘᵢₙ to the frequency control value indicated in the value of the feedback signal P2. For example, the feedback signal may have a value p_{w}, where p_{w} is any of the values p₀ to P_{N-1}. The value p_{w} is indicative of a corresponding frequency control value d_{w}. The controller 1330 then interprets the frequency control value d_{w} as the minimum frequency control value. In particular, the controller 1330 sets the minimum frequency control value Vₘᵢₙ to d_{w}. As such, each time the value of the feedback signal P2 is updated to a new value (e.g. p_{w±}1), the controller 1030 correspondingly updates the minimum frequency control value Vₘᵢₙ (e.g. to d_{w±}1).

The controller 1330 is configured to output the command signal X2 when the current value of the frequency control signal D (i.e. the current frequency control value in the sequence) is the minimum frequency control value Vₘᵢₙ. In other words, the controller 1330 may output the command signal X2 when it outputs the minimum frequency control value Vₘᵢₙ at the frequency control output 334. This will cause the digital feedback circuit 310-2 to perform the update cycle whilst v(t) is being generated by the DCO 110 at the minimum instantaneous frequency Fₘᵢₙ. As such, the digital feedback circuit 310-2 will adjust or update the digital feedback signal P2 in such a way to reduce or minimise an error between the minimum instantaneous frequency Fₘᵢₙ of the output signal v(t), and the target frequency value F_{target2}. For example, as described previously, the feedback circuit 310-2 may measure the instantaneous frequency Fₘᵢₙ, determine an error between the measured frequency and the frequency target F_{target2}, and then adjust or update the feedback signal P2 based on the error. The feedback circuit 310-2 may function as described in connection with the previously described examples, and therefore the detailed functioning of the feedback circuit 310-2 is not repeated here.

When the feedback signal P2 is adjusted, the controller 1330 will adjust the value of the parameter Vₘᵢₙ accordingly. As described above, the frequency control signal D is generated using only the frequency control values Vₘᵢₙ to Vₘₐₓ. Therefore, in turn, an adjustment to the minimum frequency control value Vₘᵢₙ will cause a corresponding adjustment to the minimum instantaneous frequency Fₘᵢₙ of the output signal v(t). This will cause a change in the bandwidth ΔF and centre frequency f_{c} of the signal v(t). For example, if the feedback signal P2 is incremented (e.g. from p_{w} to p_{w+1}), the controller 1330 will accordingly increment the minimum frequency control value Vₘᵢₙ (e.g. from d_{w} to d_{w+1}). The minimum frequency Fₘᵢₙ of the signal v(t) will therefore increase (e.g. from f_{w} to f_{w+1}), which effectively decreases the bandwidth ΔF and increases the centre frequency f_{c} of the signal v(t). If the feedback signal P2 is decremented (e.g. from p_{w} to p_{w-1}), the controller 1330 will accordingly decrement the minimum frequency control value Vₘᵢₙ (e.g. from d_{w} to d_{w-1}). The minimum frequency Fₘᵢₙ of the signal v(t) will therefore decrease (e.g. from f_{w} to f_{w-1}), which effectively increases the bandwidth ΔF and decreases the centre frequency f_{c} of the signal v(t). If the feedback signal P2 is left unchanged (e.g. because the error is within a tolerance range), the controller 1330 will leave the minimum frequency control value Vₘᵢₙ unchanged. The bandwidth and centre frequency of the signal v(t) may therefore remain unchanged.

As such, each time the controller 1330 outputs the command signal X2, the error between the minimum instantaneous frequency Fₘᵢₙ of the signal v(t) and the target frequency F_{target2} will be reduced or minimised. The controller 1330 may output the command signal X2 each time (or at least some of the times) the frequency control signal D is at the minimum value Vₘᵢₙ. Over time, the oscillator circuit 1000 is able to maintain the minimum instantaneous frequency Fₘᵢₙ of the output signal v(t) substantially at, or within a tolerance range of, the target frequency F_{target2}.

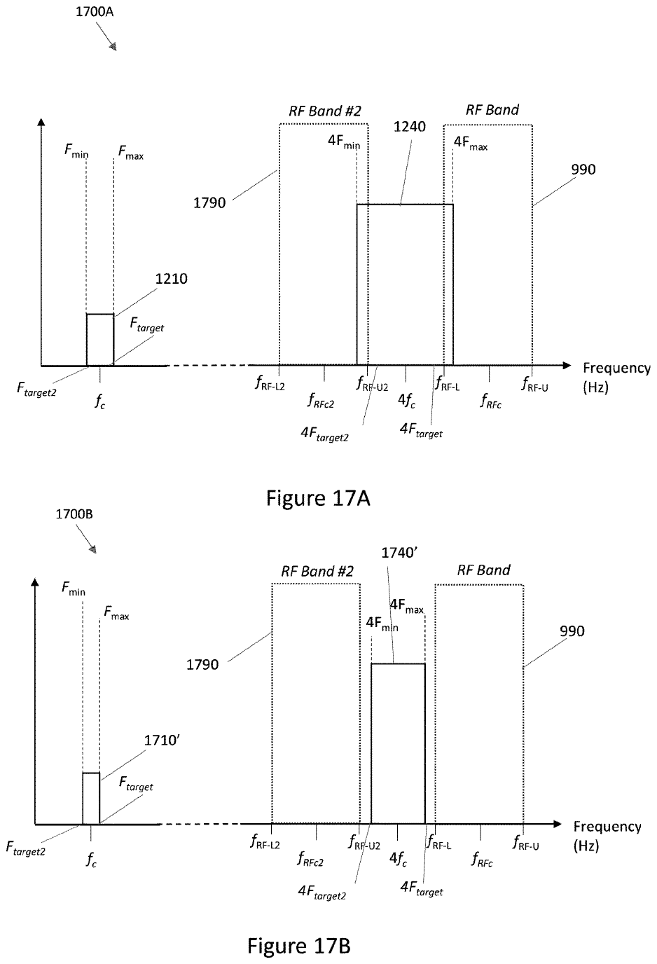

Reference is made to FIG. 17A which shows an initial electromagnetic emissions spectrum 1700A of the output signal v(t) generated by the circuit 1300. If the RF transceiver is a multi-band transceiver that operates in a second RF band 1790 in addition the RF band 990. As shown, the emissions band 1240 may also overlaps with the RF band 1790. In particular, the lower frequency 4Fₘᵢₙ is initially less than the upper frequency f_{RF-U2} of the RF band 1790. This means that over time, the signal v(t) will be modulated to instantaneous frequencies that are within the RF band 1790. As described previously, this may cause interference with the wireless signals transmitted or received by the RF transceiver.

The target frequency F_{target2} may be selected to meet the condition k*F_{target2}>f_{RF-U2}, where in this case k=4. Using the circuit 1300, the minimum frequency Fₘᵢₙ of the signal v(t) can be maintained substantially at, or within a tolerance range of, the target frequency F_{target2}. In particular, the controller 1330 can provide the command signal X2 to the digital feedback circuit 310-2 each time (or at least some of the times) that the DCO 110 is operating at the frequency Fₘᵢₙ. Each time the digital feedback circuit 310-2 receives the command signal X2, the digital feedback circuit 310-2 will perform an update cycle as described above, in order to reduce the error between the frequency Fₘᵢₙ of the output signal v(t) and the target frequency F_{target2}. Over time, this will ensure that the frequency Fₘᵢₙ of the signal v(t) stays at the target frequency F_{target2}.

FIG. 17B shows an emissions spectrum 1700B after running one or more update cycles of the digital feedback circuits 310 and 310-2. As shown, the maximum frequency Fₘₐₓ of the signal v(t) may be at the target frequency F_{target}. Furthermore, the minimum frequency Fₘᵢₙ of the signal v(t) may be at the target frequency F_{target2}. Accordingly, the frequency range of the fundamental harmonic is adapted to F_{target2} to F_{target}. The frequency range of the fourth harmonic emissions 1240′ is now between 4F_{target2} to 4F_{target}, where 4F_{target}<f_{RF-L} and 4F_{target2}>f_{RF-U2}. The controller 1330 can continue to output the command signal X to run update cycles when the DCO 110 is operating at Fₘₐₓ, in order to maintain Fₘₐₓ at F_{target}. Furthermore, the controller 1330 can continue to output the command signal X2 to run update cycles when the DCO 110 is operating at Fₘᵢₙ, in order to maintain Fₘᵢₙ at F_{target2}.

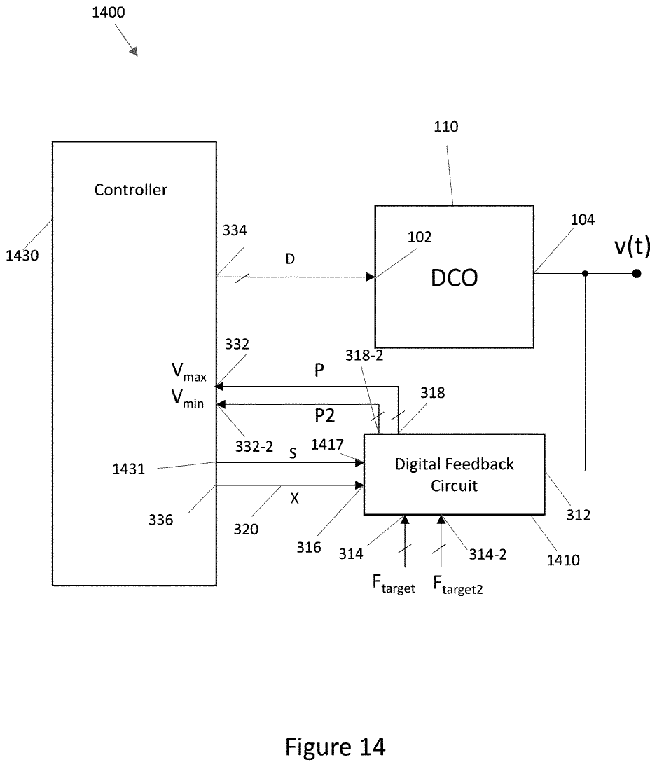

FIG. 14 shows an oscillator circuit 1400 according to another example of the present disclosure. The oscillator circuit 1400 is similar to the oscillator circuit 1300, but provides an alternative arrangement for simultaneously adapting Fₘᵢₙ and Fₘₐₓ of the output signal v(t).

The oscillator circuit 1400 includes a controller 1430 and a digital feedback circuit 1410. The controller 1430 is similar to the controller 1330, but differs as follows. The controller 1430 has one command output 336 for outputting one command signal X (i.e. the second command output 336-2 and second command signal X2 is omitted). Instead, the controller 1430 has a select output 1431 configured to output a select signal S. The select signal can have a first state (e.g. “0” or low) and a second state (e.g. “1” or high).

The oscillator circuit 1400 includes a (interleaved) digital feedback circuit 1410. The digital feedback circuit 1410 is configured to receive the signal v(t), the target frequency F_{target} and the command signal X, and output the feedback signal P, as described in connection with the feedback circuit 310. The digital feedback circuit 1410 is also configured to receive the second target frequency F_{target2} and output the second feedback signal P2 as described in connection with the feedback circuit 310-2. However, the second command input 316-2 is omitted. Instead, the digital feedback circuit 1410 is configured to receive the select signal S at a select input 1417. The digital feedback circuit 1410 is configured to operate in a first mode when the select signal S is in the first state, and in a second mode when the select signal S is in the second state.

When the digital feedback circuit 1410 is in the first mode and receives the command signal X (e.g. a pulse), the digital feedback circuit 1410 will perform an update cycle in the first mode. The digital feedback circuit 1410 will update the feedback signal P based on the signal v(t) and the target frequency F_{target}. In particular, the digital feedback circuit 1410 adjusts or updates the digital feedback signal P in such a way to reduce or minimise an error between the current instantaneous frequency of the output signal v(t) and the target frequency value F_{target}. When the digital feedback circuit 1410 is in the second mode and receives the command signal X (e.g. the pulse), the digital feedback circuit 1410 performs an update cycle in the second mode. The digital feedback circuit 1410 will update the feedback signal P2 based on the signal v(t) and the frequency target F_{target2}. In particular, the digital feedback circuit 1410 will adjust or update the digital feedback signal P2 in such a way to reduce or minimise an error between the current instantaneous frequency of the output signal v(t) and the target frequency value F_{target2}.

The controller 1430 is configured to control the digital feedback circuit 1410 as follows. When the current value of the frequency control signal D (i.e. the current frequency control value in the sequence) is the maximum frequency control value Vₘₐₓ, the controller 1410 will set the select signal S to the first state, and output the command signal X (e.g. a pulse). This will cause the digital feedback circuit 1410 to perform an update cycle in the first mode, whilst v(t) is being generated by the DCO 110 at the maximum instantaneous frequency Fₘₐₓ. As such, the digital feedback circuit 1410 will adjust or update the digital feedback signal P in such a way to reduce or minimise an error between the minimum instantaneous frequency Fₘₐₓ of the output signal v(t), and the target frequency value F_{target}. Therefore, in the first mode, the digital feedback circuit 1410 achieves the same functionality as the feedback circuit 310 described previously.

When the current value of the frequency control signal D (i.e. the current frequency control value in the sequence) is the minimum frequency control value Vₘᵢₙ, the controller 1410 will set the select signal S to the second state, and output the command signal X (e.g. a pulse). This will cause the digital feedback circuit 1410 to perform an update cycle in the second mode, whilst v(t) is being generated by the DCO 110 at the minimum instantaneous frequency Fₘᵢₙ. As such, the digital feedback circuit 1410 will adjust or update the digital feedback signal P2 in such a way to reduce or minimise an error between the minimum instantaneous frequency Fₘᵢₙ of the output signal v(t), and the target frequency value F_{target2}. Therefore, in the second mode, the digital feedback circuit 1410 achieves the same functionality as the feedback circuit 310 described previously.

The controller 1430 may operate the feedback circuit 1410 in the first mode each time (or at least some of the times) that the DCO 110 operates at the maximum frequency Fₘₐₓ. Moreover, the controller 1430 may operate the feedback circuit 1410 in the second mode each time (or at least some of the times) that the DCO 110 operates at the minimum frequency Fₘₐₓ.

In view of the above, the oscillator circuit 1400 may achieve the same result described in connection with FIGS. 12A and 12B. Advantageously, by operating one digital feedback circuit 1410 in two modes, hardware resources can be shared, and thereby reduced, whilst achieving similar functionality.

The controller 1430 may be considered as providing a first control instruction to the feedback circuit 1410, in which the controller 1430 sets the select signal S to the first state and provides the command signal X, in order to cause the feedback circuit 1410 to update the feedback signal P. The controller 1430 may also be considered as providing a second control instruction to the feedback circuit 1410, in which the controller 1430 sets the select signal S to the second state and provides the command signal X, in order to cause the feedback circuit 1410 to update the second feedback signal P2.

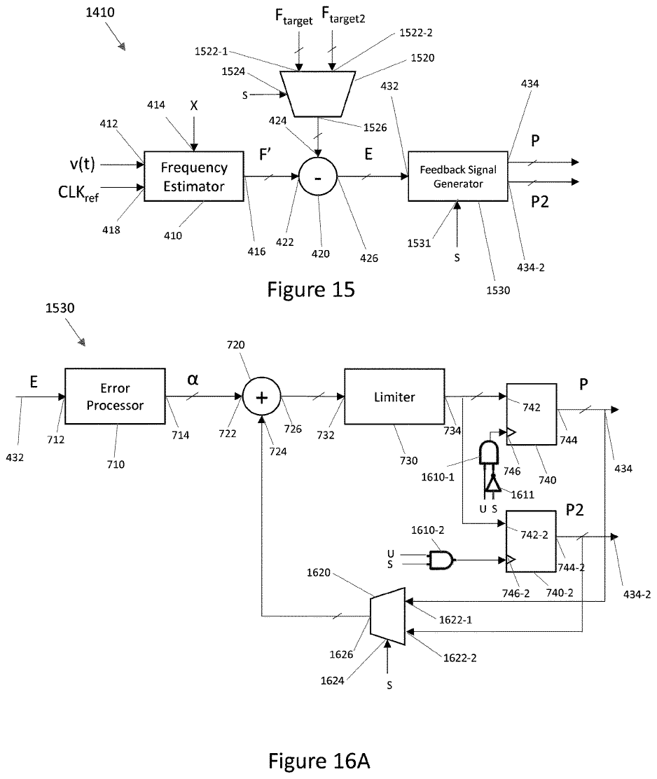

FIG. 15 shows the digital feedback circuit 1410 in more detail. The digital feedback circuit 1410 is similar to the digital feedback circuit 310, but is modified as follows.

The digital feedback circuit 1410 includes a multiplexer (MUX) 1520. The MUX 1520 receives the frequency target value F_{target} at a first input 1522-1 and the second frequency target value F_{target2} at a second input 1522-2. An output 1526 of the MUX 1520 is coupled to the second input 424 of the digital subtractor 420. The MUX 1520 receives the select signal S at a control input 1524. When the select signal S is in the first state, the MUX 1520 provides the target frequency value F_{target} at the first input 1522-1 to the output 1526. When the select signal S is in the second state, the MUX 1520 provides the target frequency value F_{target2} at the second input 1522-2 to the output 1526. As such, in the first mode of the digital feedback circuit 1410, the subtractor 420 will determine the error E between the frequency estimate F′ and the target frequency value F_{target} where E=F′-F_{target}. In the second mode of the digital feedback circuit 1410, the subtractor 420 will determine the error E between the frequency estimate F′ and the target frequency value F_{target2} where E=F′-F_{target2}.

The digital feedback circuit 1410 includes a feedback signal generator 1530. The feedback signal generator 1530 is similar to the feedback signal generator 430. However, the feedback signal generator 1530 receives the select signal S at a control input 1531. The feedback signal generator 1530 is also configured to output the second feedback signal P2 at a second output 434-2. When the select signal S is in the first state, the feedback signal generator 1530 operates in a first mode. When the select signal S is in the second state, the feedback signal generator 1530 operates in a second mode. In the first mode, the feedback signal generator 1530 adjusts or updates the feedback signal P based on the received error value E, as described previously. For example, the feedback signal generator 1530 may increase or decrease the value of the feedback signal P, based on the error value E, as previously described. As such, when the feedback circuit 1410 is performing an update cycle in the first mode, the feedback signal generator 1530 adjusts the feedback signal P in such a way to reduce or minimise the error between the instantaneous frequency Fₘₐₓ and the target value F_{target}. In the second mode, instead of updating the signal P, the feedback signal generator 1530 adjusts or updates the feedback signal P2 based on the received error value E. For example, the feedback signal generator 1530 may increase or decrease the value of the feedback signal P2, based on the error value E, as previously described. As such, when the feedback circuit 1410 is performing an update cycle in the second mode, the feedback signal generator 1530 adjusts the feedback signal P2 in such a way to reduce or minimise the error between the instantaneous frequency Fₘᵢₙ and the target value F_{target2}.

Advantageously, the feedback circuit 1410 reuses or shares the hardware of the frequency estimator 410, the digital subtractor 420 between the two modes of operation, which may reduce the size and cost of the circuit. The feedback circuit 1410 may also share hardware of the feedback signal generator 1530 between the two modes.

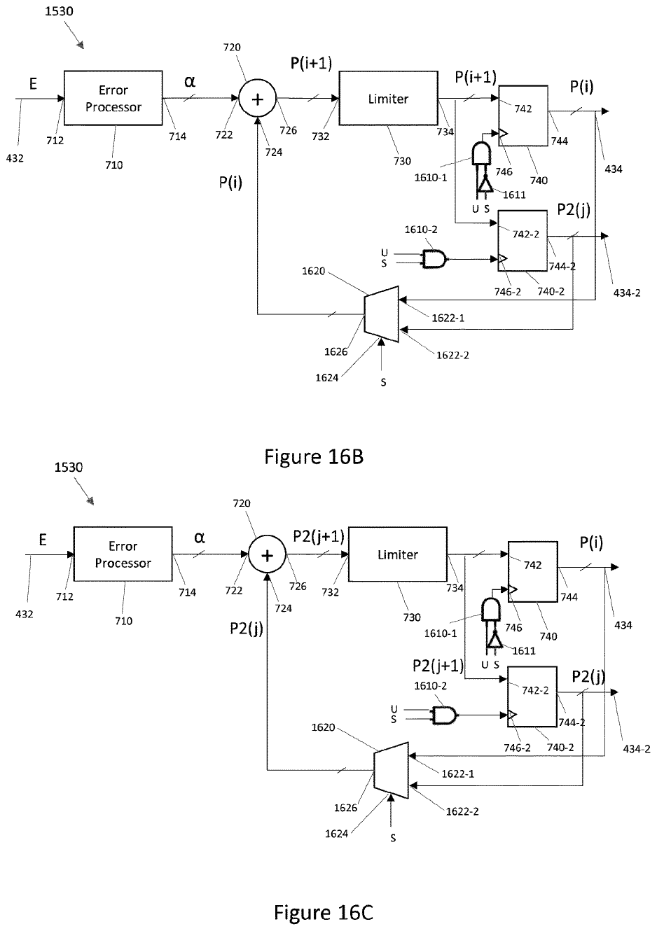

FIG. 16A shows the feedback signal generator 1530 in more detail. As shown, the feedback signal generator 1530 is similar to the feedback signal generator 430, with the following modifications.

The feedback signal generator 1530 includes a second register 740-2. An input 742-2 is coupled to the output 734 of the limiter 730. An output 744-2 of the register 740-2 corresponds to the output 434-2 of the feedback signal generator. The feedback signal generator 1530 also includes a digital AND gate 1610-2. The gate 1610-2 receives the update signal U at a first input and the select signal S at a second input. A control input 746-2 of the register 740-2 receives the output of the gate 1610-2. The register 740-2 holds the signal at its input 742-2 when the output of the gate 1610-2 is in a first state (low). The register 740-2 updates its output 744-2 (i.e. provides the signal at its input 742-2 to the output 744-2) when the output of the gate 1610-2 is in a second state (high). As such, the register 740-2 will update its output 744-2 when both U and S are in the second state (high).

The feedback signal generator 1530 also includes a digital AND gate 1610-1. The gate 1610-1 receives the update signal U at a first input and the select signal S at a second input via a digital inverter 1611. A control input 746 of the register 740 receives the output of the gate 1610. The register 740 holds the signal at its input 742 when the output of the gate 1610-1 is in a first state (low). The register 740 updates its output 744 (i.e. provides the signal at its input 742 to the output 744) when the output of the gate 1610-1 is in a second state (high). As such, the register 740 will update its output 744-2 when U is high and S is low.

The feedback signal generator 1530 also includes a MUX 1620. The MUX 1620 receives the first feedback signal P at a first input 1622-1 and the second feedback signal P2 at a second input 1622-2. An output 1626 of the MUX 1620 is coupled to the second input 724 of the digital adder 720. The MUX 1620 receives the select signal S at a control input 1624. FIG. 16B shows the feedback signal generator 1530 when in the first mode (i.e. when the digital feedback circuit 1410 is performing an update cycle in the first mode to update the feedback signal P). In the first mode, the signal S is in the first state. When S is in the first state, the MUX 1620 provides the current feedback signal P(i) at the first input 1622-1 to the output 1626, and therefore to the second input 724 of the adder 720. The adder 720 then generates the updated feedback signal P(i+1), which is in turn provided to the input 742 of the register 740, as previously described above. Then, when the update signal U transitions to the second state (high), the updated feedback signal P(i+1) will be provided to the output 744/434. Meanwhile, since the signal S is in the first state, the output of the gate 1610-2 remains low. Therefore, the register 740-2 is not updated, and therefore the feedback signal P2(j) remains unchanged.

FIG. 16C shows the feedback signal generator 1530 when in the second mode (i.e. when the digital feedback circuit 1410 is performing an update cycle in the second mode to update the feedback signal P2). In the second mode, the signal S is in the second state. When S is in the second state, the MUX 1620 provides the current feedback signal P2(j) at the second input 1622-2 to the output 1626, and therefore to the second input 724 of the adder 720. The adder 720 then generates an updated feedback signal P2(j+1) by adding the adjustment value a as described previously. The limiter 730 limits the updated feedback signal P2(j+1) as described previously. The updated feedback signal P2(j+1) is then provided to the input 742-2 of the register 740-2. Then, when the update signal U transitions to the second state (high), the updated feedback signal P2(j+1) will be provided to the output 744-2/434-2. Meanwhile, since the signal S is in the second state, the output of the gate 1610-1 remains low. Therefore, the register 740 is not updated, and therefore the feedback signal P(i) remains unchanged.

Advantageously, the feedback signal generator 1530 reuses or shares the hardware of the error processor 710, the adder 720 and the limiter 730 between the two modes of operation, which may reduce the size and cost of the circuit.

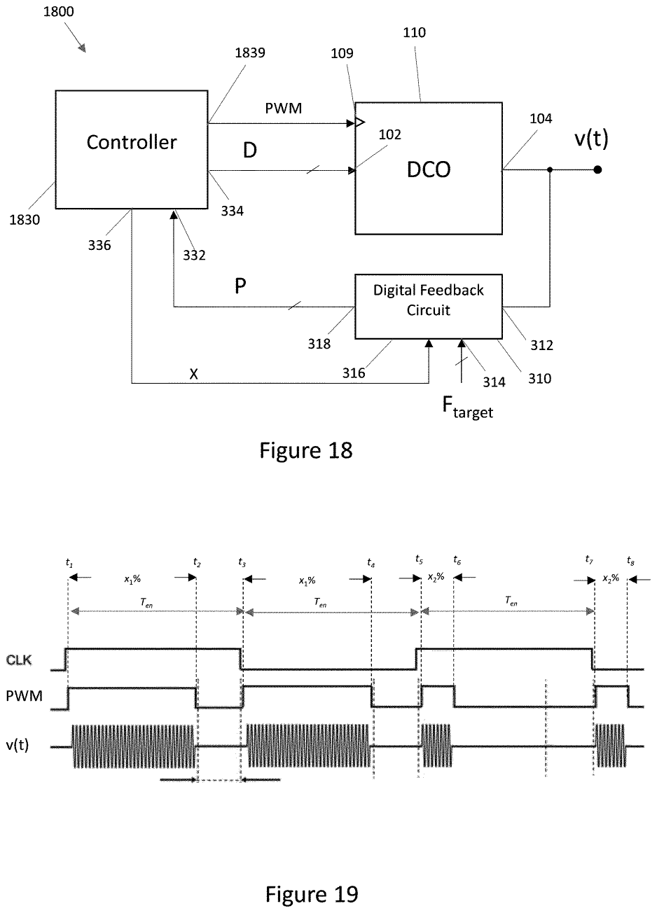

FIG. 18 shows an oscillator circuit 1800 according to another example of the present disclosure. The oscillator circuit 1800 corresponds to the circuit 300, with the following modifications.

The controller 1830 corresponds to the controller 330. However, the controller 1830 is further configured to generate pulse-width modulation (PWM) clock signal, PWM. The PWM signal is for modulating the DCO 110 output v(t) according to an on-off keying (OOK) modulation scheme. The PWM signal is shown in FIG. 19. The PWM signal has a period of Tₑₙ and frequency Fₑₙ. The PWM signal also has a variable duty ratio of x %. For each period of the PWM signal, the PWM signal will be at a first state (e.g. low) for (1−x)% of the period, and in a second state (e.g. high) for x % of the period. For example, as shown in FIG. 19, during the period t1 to t3, the duty ratio is x₁%. This results in the PWM signal being in a second state (“high”) between times t1 and t2, and in a first state (“low”) between times t2 and t3. During the period t5 to t7, the duty ratio is x₂%, where x₂%<x₁%. This results in the PWM signal being in the second state for a relatively shorter time window t5 to t6. The PWM signal toggles between the first state and the second state.

The controller 1830 is configured to output the PWM signal at an output 1839. The DCO 110 is configured to receive the PWM signal at the enable terminal 109. As such, the PWM signal will control the off and on state of the DCO 110. In particular, when the PWM signal is in the first state (low), the DCO 110 will be in the off state. When the PWM signal is in the second state (high), the DCO 110 will be in the on state. For example, as shown in FIG. 19, the DCO 110 is on and therefore generates the signal v(t) between times t1 and t2 whilst the PWM is high. The DCO 110 turns off and stops generating the signal v(t) between times t2 and t3 when the PWM signal is low. When the duty ratio is lowered to x2%, the output signal v(t) will be generated for a shorter portion of the period Tₑₙ. Accordingly, the average power of the output signal v(t) is relatively lower between the times t5 to t7 and relatively higher between the times t1 and t3. As such, the duty ratio x % can be controlled to regulate the average power of the output signal v(t). In general, the frequency fₑₙ of the PWM signal will be lower than the minimum possible frequency of the output signal v(t) (i.e. fₑₙ<f₀). The duty cycle x % may be considered as defining an on-time of each period Tₑₙ the PWM signal (and therefore the DCO), whilst the ratio (x−1)% may be considered as defining an off-time of each period Tₑₙ of the PWM signal (and therefore the DCO). The DCO toggles between the on state and the off state in response to the PWM signal.

In some examples, the output signal v(t) may be used to power a load. The load may be clocked by a clock signal CLK having the same frequency as the PWM signal. The load may perform operations in response to the falling edges of the clock signal CLK. As shown in FIG. 9, as a result of the PWM signal, the DCO 110 is turned off before each falling edge of the clock signal CLK. Advantageously, this may prevent the output signal v(t) from interfering with the operations performed by the load at the falling edge of the clock signal CLK.

It will be appreciated that in some examples, the signal PWM is not pulse-width modulated, and may instead be a clock signal with a fixed duty ratio (e.g. of 50% or otherwise).

The controller 1830 is configured to output the command signal X when the PWM signal is high (i.e. when the DCO 110 is on). This ensures that the digital feedback circuit 310 only performs an update cycle whilst the DCO 110 is on. In particular, this ensures that the frequency estimator is able to properly estimate the frequency of the oscillating signal v(t). Otherwise, if the digital feedback circuit 310 attempts to perform an update cycle whilst the DCO 110 is off, then the digital feedback circuit will attempt to adjust the feedback signal based on an invalid frequency measurement of the signal v(t) (e.g. based on a measurement of the DC “off” value of the signal v(t)).

In some examples, the controller 1830 is configured to output the command signal on the further condition that the current duty ratio x % is above a threshold ratio xₜₕᵣₑₛₕ %. This may ensure that the DCO 110 is on for a sufficient amount of time, to allow the digital feedback circuit 310 to estimate the frequency of the signal v(t) during the estimation time window.

It will be appreciated that the previously described controllers 1030/1330/1430 may also be configured to provide a PWM signal to the enable input of the DCO 110. Those controllers may therefore output the command signal X and X2 on the further condition that the PWM signal is high at the time that the command signal X and X2 is outputted (i.e. the DCO 110 is on at the time). The controllers may optionally output the command signals X and X2 on the further condition that the current duty ratio x % is above a threshold ratio xₜₕᵣₑₛₕ %, as described above.

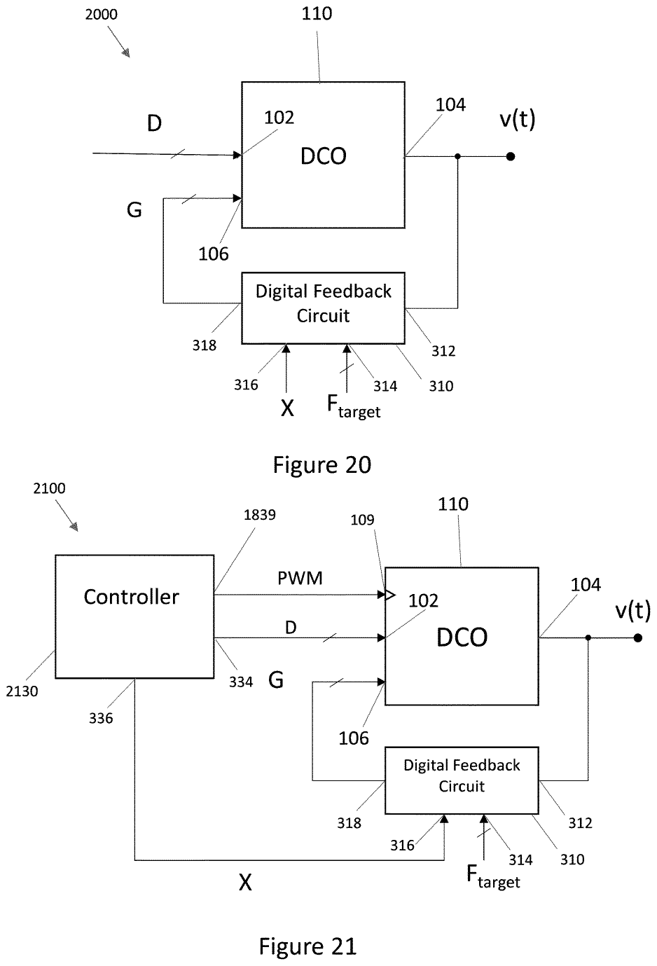

It will be appreciated that in some examples, the PWM signal is not received from the controller and may instead be received from other external circuitry, FIG. 20 shows an oscillator circuit 2000 according to another example of the present disclosure. As described below, the oscillator circuit 300 is able to maintain the instantaneous frequency F of the output signal v(t) substantially at, or at least within a tolerance range of, a target frequency F_{target}.

In the oscillator circuit 2000, the feedback signal outputted by the digital feedback circuit 310 is the offset control signal G. In particular, the digital feedback circuit 310 directly outputs the offset control signal G at the output 318. The DCO 110 receives the offset control signal G at the offset control input 106. When the feedback circuit 310 performs an update cycle, the digital feedback circuit 310 updates the value of the offset control signal G. In particular, the digital feedback circuit 310 adjusts or updates the offset control signal G in such a way to reduce or minimise an error between the instantaneous frequency F of the output signal v(t) and the target frequency value F_{target}. When the offset control signal G is adjusted, the DCO 110 will adjust the frequency offset applied to the output v(t) accordingly, which will cause the instantaneous frequency F of the output signal v(t) to be adjusted. For example, increasing the value of the offset control signal G (e.g. from gₘ to gₘ₊₁) will cause a corresponding increase in the instantaneous frequency F of the output signal v(t) (e.g. from fₙ+δfₘ to fₙ+δfₘ₊₁). Decreasing the value of the offset control signal G (e.g. from gₘ to gₘ₋₁) will cause a corresponding decrease in the instantaneous frequency F of the output signal v(t) (e.g. from fₙ+δfₘ to fₙ+δfₘ₋₁). As such, each time feedback circuit 310 receives the command signal X (e.g. from a controller), the error between the instantaneous frequency of the output signal v(t) and the target frequency F_{target} will be reduced or minimised. The feedback circuit 310 may receive the command signal X periodically (e.g. at regular intervals), or at irregular intervals. In any case, over time, the oscillator circuit 2000 is able to maintain the instantaneous frequency F of the output signal v(t) substantially at, or within a tolerance range of, the target frequency F_{target}. As such, the oscillator circuit 2000 is able to achieve the same result described in connection with FIGS. 9A and 9B.

The digital feedback circuit 310 may function as previously described, but to update the offset control signal G instead of the feedback signal P. In particular, the same arrangement of components may be used with equivalent functionality, as previously described. As such, the detailed functionality of the feedback circuit 310 in the oscillator circuit 2000 is not repeated.

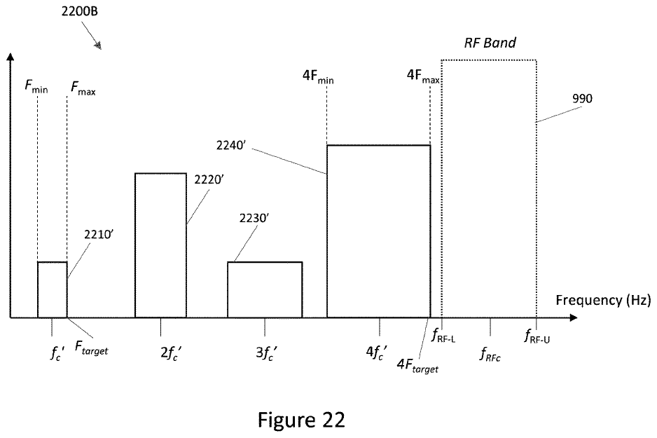

FIG. 21 shows an oscillator circuit 2100 according to another example of the present disclosure. The oscillator circuit 2100 shows that the oscillator circuit 2000 can be used with a controller 2130 that controls the DCO 110 according to a spread spectrum modulation scheme. In particular, the controller 2130 may generate the frequency control signal D as a sequence of values between Vₘᵢₙ and Vₘₐₓ, as previously described. The controller 2130 will therefore output the command signal X under the conditions previously described. In particular, if the circuit 2100 is to maintain the maximum frequency Fₘₐₓ of the signal v(t) at the target F_{target}, the controller 2130 may output the command signal X when the current value of the signal D corresponds to Vₘₐₓ. Over time, the maximum frequency Fₘₐₓ will be maintained at the target F_{target}. For example, reference is made to FIG. 22, which shows the emissions spectrum of the signal v(t) after one or more update cycles. Updating the offset control signal G will effectively shift the centre frequency f_{c} of the emissions bands 2210′-2240′. Since update cycles are only performed when the signal v(t) is at the frequency Fₘₐₓ, the centre frequency will be shifted in such a way to minimise an error between Fₘₐₓ at F_{target}.

The circuit 2100 may also be used to maintain the minimum frequency Fₘᵢₙ of the signal v(t) at the target F_{target}. In this case, the controller 2130 may output the command signal X when the current value of the signal D corresponds to Vₘᵢₙ.

The oscillator circuit 2100 also shows that the oscillator circuit 2000 can be used with a controller 2130 that uses a PWM signal (PWM) to perform OOK modulation of the DCO 110. In this case, the controller 2130 may output the command signal X on the further condition that the PWM signal is currently high (i.e. during an on-time of the PWM signal, and the DCO 110 is in the on-state). Optionally, the controller 2130 may output the command signal X on the further condition that the duty ratio x % is above a threshold xₜₕᵣₑₛₕ %.

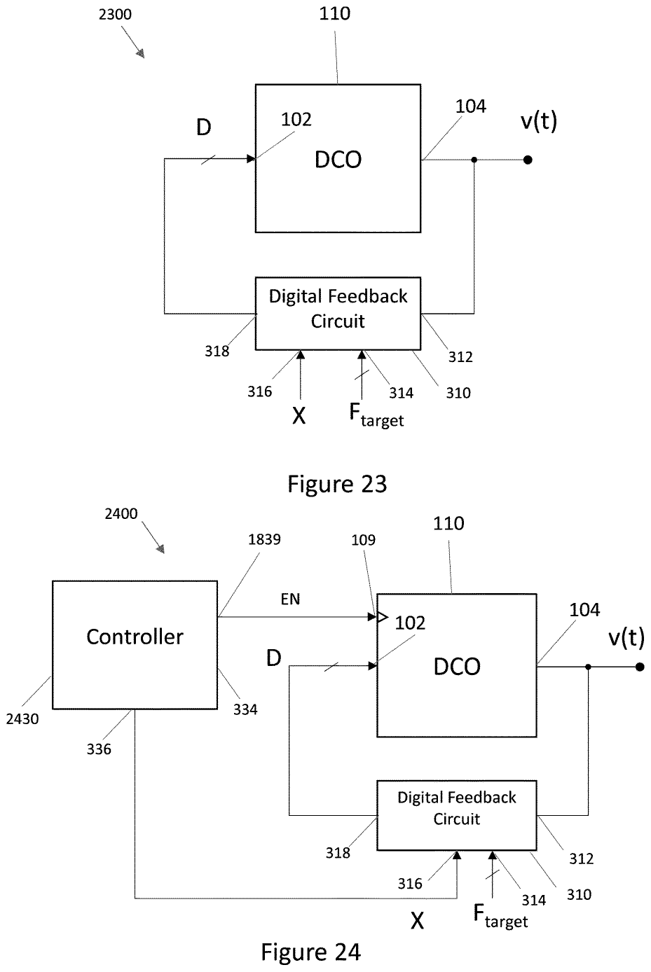

FIG. 23 shows an oscillator circuit 2300 according to another example of the present disclosure. The oscillator circuit 2300 is similar to the oscillator circuit 2000. However, the digital feedback circuit 310 is used to directly update the frequency control signal D to minimise the error between the frequency F of the signal v(t) and the target F_{target}.

In the oscillator circuit 2300, the feedback signal outputted by the digital feedback circuit 310 is the frequency control signal D. In particular, the digital feedback circuit 310 directly outputs the frequency control signal D at the output 318. The DCO 110 receives the frequency control signal D at the frequency control input 102. When the feedback circuit 310 performs an update cycle, the digital feedback circuit 310 updates the value of the frequency control signal D. In particular, the digital feedback circuit 310 adjusts or updates the frequency control signal D in such a way to reduce or minimise an error between the instantaneous frequency F of the output signal v(t) and the target frequency value F_{target}. When the frequency control signal D is adjusted, the DCO 110 will adjust the frequency of the output v(t) accordingly, which will cause the instantaneous frequency F of the output signal v(t) to be adjusted. For example, increasing the value of the frequency control signal D (e.g. from dₙ to dₙ₊₁) will cause a corresponding increase in the instantaneous frequency F of the output signal v(t) (e.g. from fₙ to fₙ₊₁). Decreasing the value of the frequency control signal D (e.g. from dₙ to dₙ₋₁) will cause a corresponding decrease in the instantaneous frequency F of the output signal v(t) (e.g. from fₙ to fₙ₋₁). As such, each time feedback circuit 310 receives the command signal X (e.g. from a controller), the error between the instantaneous frequency of the output signal v(t) and the target frequency F_{target} will be reduced or minimised. The feedback circuit 310 may receive the command signal X periodically (e.g. at regularly intervals), or at irregular intervals. In any case, over time, the oscillator circuit 2300 is able to maintain the instantaneous frequency F of the output signal v(t) substantially at, or within a tolerance range of, the target frequency F_{target}. As such, the oscillator circuit 2300 is able to achieve the same result described in connection with FIGS. 9A and 9B.

The digital feedback circuit 310 may function as previously described, but to update the frequency control signal D instead of the feedback signal P. In particular, the same arrangement of components may be used with equivalent functionality, as previously described. As such, the detailed functionality of the feedback circuit 310 in the oscillator circuit 2300 is not repeated.

FIG. 24 shows an oscillator circuit 2400 according to another example of the present disclosure. The oscillator circuit 2400 also shows that the oscillator circuit 2300 can be used with a controller 2430 that uses a PWM signal (PWM) to perform OOK modulation of the DCO 110. In this case, the controller 2430 may output the command signal X on the further condition that the PWM signal is currently high (i.e. during an on-time of the PWM signal, and the DCO 110 is in the on-state). Optionally, the controller 2430 may output the command signal X on the further condition that the duty ratio x % is above a threshold xₜₕᵣₑₛₕ %.

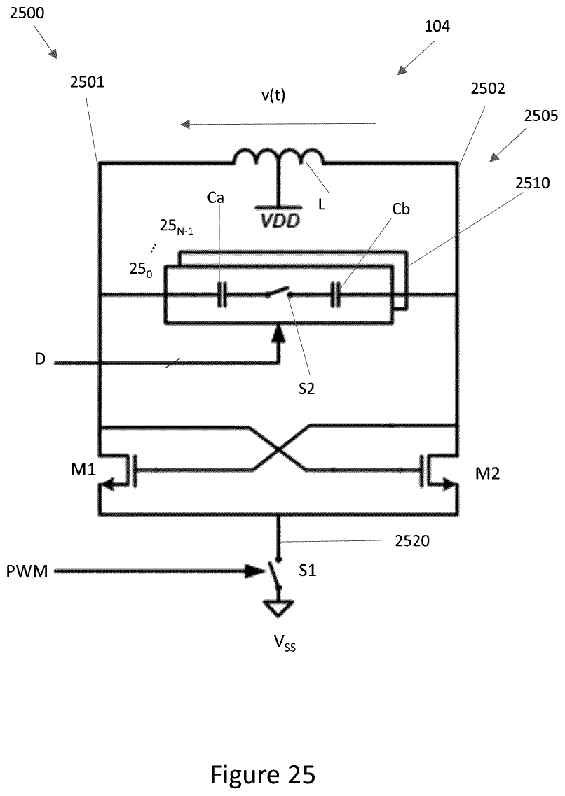

FIG. 25 shows a DCO 2500 according to an example of the present disclosure. The DCO 2500 may be used to implement the DCO 110 described previously. The output 104 of the DCO 2500 is formed of a first output node 2501 and a second output node 2502. The DCO 2500 includes a LC tank 2505. The LC tank 2505 is coupled between the output nodes 2501 and 2502 of the DCO 2500. The LC tank 2505 is formed of an inductor L and a switchable capacitor bank 2510. Where the DCO is used in a galvanically isolated power transfer circuit as discussed herein, the inductor L may correspond to a primary winding of a transfer used to transfer the oscillator signal across an isolation barrier. Each of the inductor L and the capacitor bank 2510 are connected in parallel between the output nodes 2501 and 2502, and therefore in parallel to one another. The DCO 2500 further includes a first MOS transistor M1 and a second MOS transistor M2. In this example, the transistors M1 and M2 are N-type MOS transistors, but it will be appreciated that P-type MOS transistors may alternatively be used. It will be appreciated that complimentary PMOS/NMOS structures and variants are well-known in the literature. A gate of M1 is coupled to the output node 2502. A drain of M1 is coupled to the output node 2501. A gate of M2 is coupled to the output node 2501. A drain of M2 is coupled to the output node 2502. The sources of M1 and M2 are coupled to one another at a common node 2520. A switch S1 is coupled between the common node 2520 and a low supply voltage V_{SS}.

The switchable capacitor bank 2510 is configured to provide any one of a plurality of N capacitances C₀ to C_{N-1} in parallel with the inductor L. In particular, the capacitor bank 2510 is configured to receive any one of the plurality of N digital frequency control values or codes d₀ to d_{N-1} via the frequency control signal D. The capacitor bank 2510 provides a capacitance Cₙ corresponding to the current value dₙ of the frequency control signal D. The instantaneous frequency F of the output signal v(t) is proportional to the capacitance of the capacitor bank 2510. As such, the DCO 2500 generates the output signal v(t) at the instantaneous frequency fₙ corresponding to the capacitance Cₙ of the capacitor bank 2510, e.g. as shown in FIG. 2. The capacitances C₀ to C_{N-1} increase in increments of a unit capacitance Cᵤₙᵢₜ. In alternative examples, the capacitances C₀ to C_{N-1} may increase non-uniformly, to produce linear-in-frequency digital control.

The capacitor bank 2510 is formed of N capacitor circuits 25₀ to 25_{N-1}. The capacitor circuits 25₀ to 25_{N-1} are connected in parallel to one another between the output nodes 2501 and 2502. Each capacitor circuit 25ₙ is operable in a first switched state in which the capacitor circuit 25ₙ contributes the unit capacitance Cᵤₙᵢₜ to the total capacitance of the capacitor bank 2510. Each capacitor circuit 25ₙ is also operable in a second switched state in which the capacitor circuit 25n does not contribute any capacitance to the capacitor bank 2510. The frequency control value dₙ controls the states of each of the capacitor circuits 25₀ to 25_{N-1} so that the capacitor bank 2510 has the corresponding capacitance Cₙ. In particular, the frequency control code dₙ may cause the capacitor circuits 25₀ to 25ₙ to be in the first switched state, and the capacitor circuits 25ₙ₊₁ to 25_{N-1} to be in the second switched state. As a result, an appropriate number of unit capacitances Cᵤₙᵢₜ are provided between the output nodes 2501 and 2502 to add up to the capacitance Cₙ required to generate the output signal v(t) at the frequency fₙ.

Each capacitor circuit 25n is formed of a first capacitor Cₐ, a second capacitor C_{b} and a switch S2. The switch S2 is serially connected in between the first capacitor Ca and the second capacitor Cb. When the switch S2 is closed, the capacitor circuit 25ₙ is in the first switched state in which the capacitor circuit 25ₙ contributes a unit capacitance Cᵤₙᵢₜ to the total capacitance of the of the capacitor bank 2510. The unit capacitance Cᵤₙᵢₜ is formed of the series combination of the first capacitance Ca and the second capacitor Cb. When the switch S2 is open, the capacitor circuit 25ₙ is in the second switched state. It will be appreciated that other switched-capacitor arrangements are known and may be used to implement the capacitor circuits 25₀-25_{N-1}.

The switch S1 is configured to receive the PWM signal PWM. When the PWM signal is high, the switch S1 is closed. When the enable signal is low, the switch S1 is open. When the switch S1 is closed, the DCO 2500 will be in the on state and output the output signal v(t) at the instantaneous frequency fₙ determined by the frequency control value dₙ. When the switch S1 is open, the DCO 2500 will be in the off state, and will not output the signal v(t).

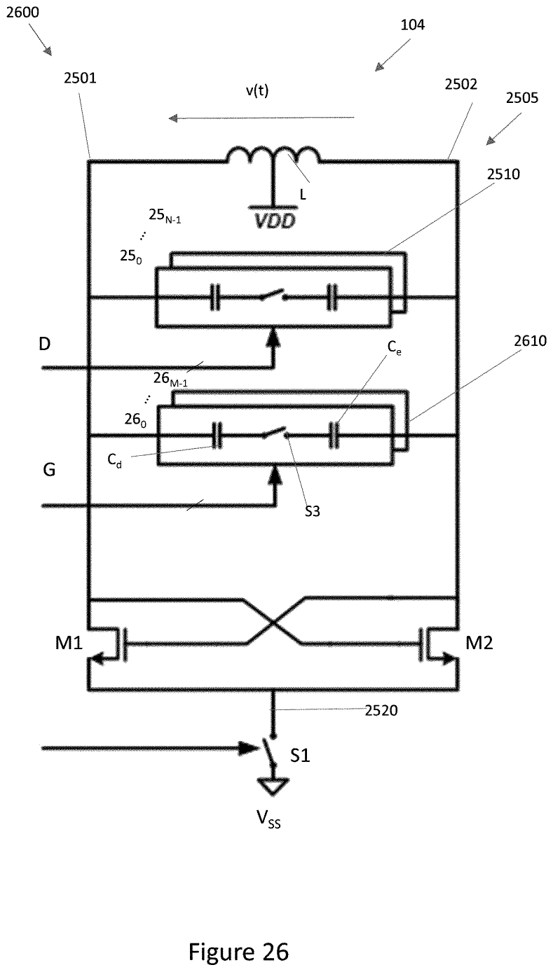

FIG. 26 shows another example DCO 2600 of the present disclosure. FIG. 26 shows how the DCO 2500 can be modified to be able to apply a frequency offset to the output signal v(t) based on the frequency offset control signal G.

The DCO 2600 further includes a capacitor bank 2610 formed of M capacitor circuits 260 to 26_{M-1}. The capacitor bank 2610 is connected in parallel with the capacitor bank 2510 and the inductor L. The capacitor bank 2610 provides an additional M capacitances Co to C_{M-1} in parallel with the bank 2510 and inductor L. In particular, the capacitor bank 2610 is configured to receive any one of the plurality of M digital offset control values or codes g₀ to g_{M-1} via the offset control signal G. The capacitor bank 2610 provides a capacitance Cₘ corresponding to the current value gₘ of the offset control signal D. The instantaneous frequency F of the output signal v(t) is proportional to the capacitance of the capacitor bank 2510. As such, the DCO 2500 generates the output signal v(t) at the instantaneous frequency fₙ+δfₘ, where δfₘ corresponds to the capacitance Cₘ of the capacitor bank 2610. The capacitor bank 2610 is similar to the capacitor bank 2510. In particular, the capacitor circuits 26₀ to 26_{M-1} are similar to those of the capacitor bank 2510 and are not described in detail.

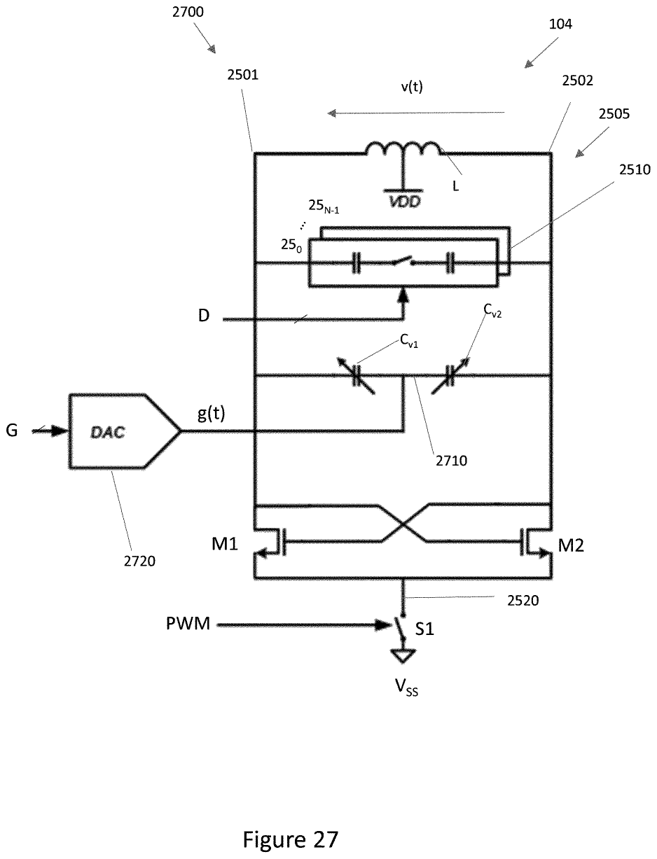

FIG. 27 shows another example DCO 2700 of the present disclosure. FIG. 27 shows another example of how the DCO 2500 can be modified to be able to apply a frequency offset to the output signal v(t) based on the frequency offset control signal G.

The DCO 2700 includes a first variable capacitor Cᵥ₁ and a second variable capacitor Cᵥ₂ coupled in series between the output nodes 2501 and 2502, with a common node 2710 in between the capacitors Cᵥ₁ and Cᵥ₂. The capacitors Cᵥ₁ and Cᵥ₂ may be varactor tuning capacitors. The DCO 2700 further includes a digital to analog converter (DAC) 2720. The DAC 2720 receives the offset control signal G at its input. The DAC 2720 converts the offset control signal to an analog voltage signal g(t). The analog signal g(t) is provided to the common node 2720 in order to apply the corresponding frequency offset to the output signal v(t). The DAC 2720 may be any type of DAC.

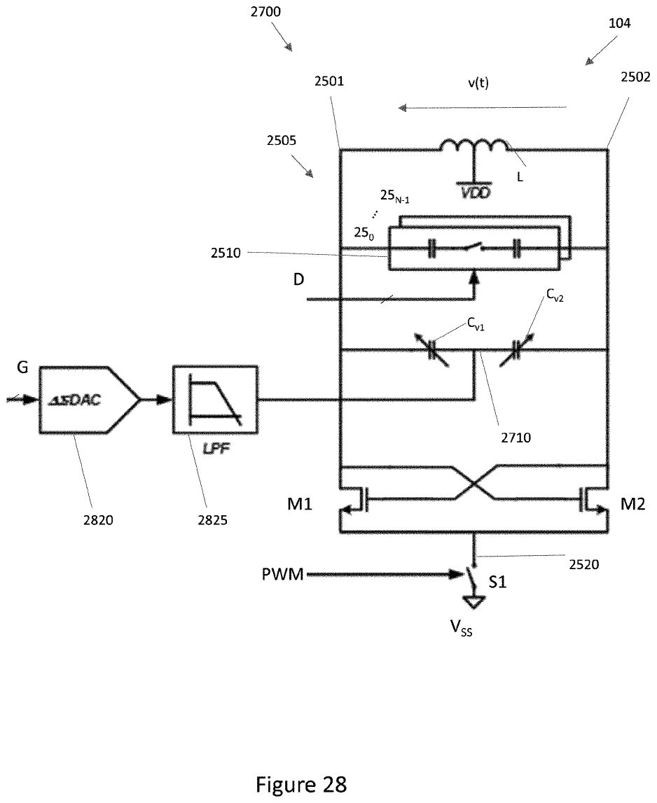

FIG. 28 shows another example DCO 2800 of the present disclosure. In the DCO 2800, a delta-sigma DAC 2820 is used in combination with a low pass filter (LPF) 2825. In particular, the DAC 2820 receives the offset control signal G and converts it to delta-sigma output signal. The LPF 2825 low-pass filters the output of the DAC 2820. The low-pass filtered signal is then provided to the node 2710 from the output of the LPF. Here the resolution of the offset adjustment is determined by the effective resolution of the delta-sigma DAC 2820, with quantization noise filtered by the low pass filter. Advantageously, very high offset resolution can easily be attained employing well known delta-sigma techniques.

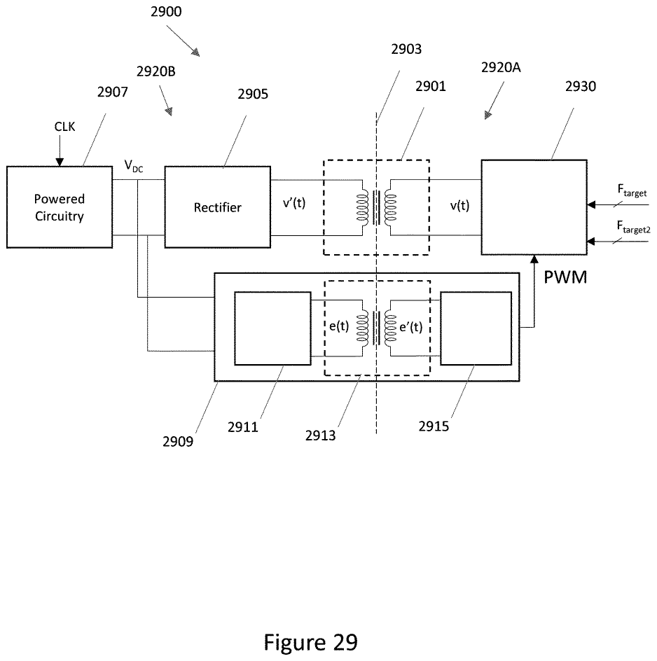

FIG. 29 shows an example of how the oscillator circuits of the present disclosure may be used in a galvanically isolated power transfer circuit 2900. The power transfer circuit 2900 includes a first circuit region or domain 2920A and a second circuit region of domain 2920B. The first circuit region 2920A is galvanically isolated from the second circuit region 2920B via a galvanic isolation barrier 2903. The first circuit region 2920A includes an oscillator circuit 2930. The oscillator circuit 2930 may be any oscillator circuit described herein and outputs the oscillator output signal v(t). The circuit 2900 includes a transformer 2901. The transformer 2901 receives the signal v(t) at its primary winding, and transfers it across the isolation barrier 2903 to its secondary winding. The transferred signal is denoted v′(t). The second circuit region 2920B of the circuit 2900 includes a rectifier 2905 which receives the (AC) signal v′(t) and rectifies it to generate and output a DC voltage supply V_{DC}. The DC voltage VDC is then supplied to powered circuitry 2907 included in the second circuit region 2920B of the circuit 2900. As such, the oscillator circuit 2930 is used to supply power to the powered circuitry 2907 across the isolation barrier 2903.

In some examples, the circuit 2900 also includes a feedback circuitry 2909. The feedback circuitry 2909 implements a feedback loop to maintain the power level supplied to the powered circuitry 2907 at a predetermined or target power level. In particular, the feedback circuit 2909 generates a PWM signal for maintaining the power level at the target power level. The PWM signal is supplied to the oscillator circuit 2930, and controls the on-off key (OOK) modulation of the DCO of the oscillator circuit 2930 as described herein. As such, as previously described, the average power of the signal v(t) will be dependent on the duty cycle of the PWM signal. The feedback circuit 2909 thus controls the duty cycle of the of the PWM signal to meet the target power level at the powered circuitry 2907. The feedback circuit 2909 includes first circuitry 2911 in the second circuit region 2920B, which determines an error between the DC voltage V_{DC} and a reference voltage indicative of the target power level. The error may be determined using a comparator. The circuitry 2911 then encodes the error into an AC signal e(t). The circuit 2909 includes a transformer 2913 which receives the signal e(t) at its primary winding in the second circuit region 2920B. The transformer 2913 transfers the signal e(t) across the isolation barrier 2903, where the transferred signal is denoted e′(t). The circuit 2909 includes second circuitry 2915 in the first circuit region 2920A which receives the transferred error signal e′(t). The circuitry 2915 decodes the error from the signal e′(t) and adjusts the PWM signal based on the error in order to minimise the error. Consequently, the average power of the signal v(t) is adjusted accordingly, which causes an adjustment to the voltage V_{DC} received at the powered circuitry 2907 in such a way to reduce the error between the voltage V_{DC} and the reference voltage.

It will be appreciated that the circuits described herein may be implemented as integrated circuits, in FPGAs and/or in chip-scale packages.

1. An oscillator circuit comprising:
a controller configured to generate a frequency control signal, the frequency control signal comprising a first frequency control value;
a digitally controlled oscillator (DCO) configured to generate, based on the frequency control signal, an oscillator output signal, wherein the output signal is generated at a first frequency in response to the first frequency control value of the frequency control signal; and
a digital feedback circuit configured to receive the output signal and output a first feedback signal, wherein the oscillator circuit is configured such that the first frequency is dependent on, or based at least in part on, a value of the first feedback signal,
wherein the controller is configured provide a first control instruction to instruct the digital feedback circuit to update the first feedback signal, wherein the digital feedback circuit is configured to, in response to the first control instruction:
measure the first frequency of the output signal; and
adjust the value of the first feedback signal to reduce an error between the first frequency and a first target frequency.

2. The oscillator circuit of claim 1, wherein the controller is configured to discontinuously or aperiodically provide the first control instruction to the digital feedback circuit.

3. The oscillator circuit of claim 1, wherein the digital feedback circuit is configured to adjust the value of the first feedback signal in response to an update control instruction, and wherein the controller is configured to provide the update control instruction at a different time to providing the first control instruction.

4. The oscillator circuit of claim 1, wherein the frequency control signal comprises a sequence of discrete frequency control values ranging from the first frequency control value to a second frequency control value,
wherein the DCO is configured to generate the output signal at an instantaneous frequency corresponding to a current value of the frequency control signal,
wherein the controller is configured provide the first control instruction when the current value of the frequency control signal corresponds to the first frequency control value.

5. The oscillator circuit of claim 4,
wherein the oscillator circuit further comprises a second digital feedback circuit configured to receive the output signal and output a second feedback signal,
wherein the controller is configured to receive the first feedback signal and the second feedback signal and generate the frequency control signal based on the first feedback signal and the second feedback signal, wherein the first frequency control value is proportional to the value of the first feedback signal and the second frequency control value is proportional to a value of the second feedback signal,
wherein the output signal is generated at a second frequency in response to the second frequency control value of the frequency control signal, and
wherein the controller is further configured to provide a second control instruction to instruct the second digital feedback circuit to update the second feedback signal, wherein the controller is configured to provide the second control instruction when the current value of frequency control signal corresponds to the second frequency control value, wherein the second digital feedback circuit is configured to, in response to the second control instruction:
measure of the second frequency of the output signal; and
adjust the value of the second feedback signal to reduce an error between the second frequency and a second target frequency.

6. The oscillator circuit of claim 1, wherein the digital feedback circuit is configured to, in response to the first control instruction:
measure the first frequency within a time window initiated by the first control instruction,
determine an error between the first frequency and the first target frequency; and
adjust the value of the first feedback signal based on the determined error.

7. The oscillator circuit of claim 6, wherein adjusting the value of the first feedback signal comprises one of:
increasing the value of the first feedback signal if the error indicates that the first frequency is less than the first target frequency, and decreasing the value of the first feedback signal if the error indicates that the first frequency is greater than the first target frequency;
increasing the value of the first feedback signal if the error indicates that the first frequency is less than the first target frequency by a first threshold amount, and decreasing the value of the first feedback signal if the error indicates that the first frequency is greater than the first target frequency by a second threshold amount; or
if the error is greater than a previous error between the first frequency and the first target frequency, then: increasing the value of the first feedback signal if the error indicates that the first frequency is less than the first target frequency, and decreasing the value of the first feedback signal if the error indicates that the first frequency is greater than the first target frequency by a first threshold amount; and if the error is less than the previous error, then: increasing the value of the first feedback signal if the error indicates that the first frequency is less than the first target frequency by a second threshold amount, and decreasing the value of the first feedback signal if the error indicates that the first frequency is greater than the first target frequency.

8. The oscillator circuit of claim 4, wherein the digital feedback circuit is configured to output a second feedback signal,
wherein the controller is further configured to receive the first feedback signal and the second feedback signal and generate the frequency control signal based on the first feedback signal and the second feedback signal, wherein the first frequency control value is proportional to the value of the first feedback signal and the second frequency control value is proportional to a value of the second feedback signal,
wherein the output signal is generated at a second frequency in response to the second frequency control value of the frequency control signal,
wherein the controller is configured to provide the first control instruction when the current value of frequency control signal corresponds to the first frequency control value, and provide a second control instruction to instruct the digital feedback circuit to update the second feedback signal, wherein the controller provides the second control instruction when the current value of frequency control signal corresponds to the second frequency control value, and
wherein the digital feedback circuit is configured to, in response to the second control instruction:
measure the second frequency of the output signal; and
adjust the value of the second feedback signal to reduce an error between the second frequency and a second target frequency.

9. The oscillator circuit of claim 8, wherein the digital feedback circuit is configured to:
in response to the first control instruction:
measure, using a frequency estimation circuit, the first frequency within a time window initiated by the first control instruction,
determine, using a digital subtractor, an error between the first frequency and the first target frequency; and
adjust the value of the first feedback signal based on the determined error; and
in response to the second control instruction:
measure, using the frequency estimation circuit, the second frequency within a time window initiated by the second control instruction,
determine, using the digital subtractor, an error between the second frequency and a second target frequency; and
adjust the value of the first feedback signal based on the determined error,
wherein the digital feedback circuit further comprises a multiplexer configured to provide the first target frequency to the subtractor in response to the first control instruction, and provide the second target frequency to the subtractor in response to the second control instruction.

10. The oscillator circuit of claim 9, wherein the digital feedback circuit is configured to:
in response to the first control instruction:
generate, using an error processing circuit and based on the error between the first frequency and the first target frequency, an adjustment value indicative of a desired adjustment to the value of the first feedback signal to reduce the error, and
adjust the first feedback signal by adding, using a digital adder, the adjustment value to the first feedback signal; and
in response to the second control instruction:
generate, using the error processing circuit and based on the error between the second frequency and the second target frequency, an adjustment value indicative of a desired adjustment to the value of the second feedback signal to reduce the error, and
adjust the second feedback signal by adding, using the digital adder, the adjustment value to the second feedback signal,
wherein the digital feedback circuit further comprises:
a first output configured to output the first feedback signal and a second output to output the second feedback signal; and
a multiplexer configured to provide the first feedback signal from the first output to the adder in response to the first control instruction, and provide the second feedback signal from the second output to the adder in response to the second control instruction.

11. The oscillator circuit of claim 1, wherein the controller is configured to provide a clock signal to the DCO, wherein the DCO is configured to toggle between an on state and an off state in response to the clock signal; and
wherein the controller is configured to provide the first control instruction when the DCO is in the on state.

12. The oscillator circuit of claim 11, wherein the clock signal is a pulse-width modulated (PWM) clock signal, the PWM signal having a duty cycle defining an on-time of the PWM signal, wherein the DCO is configured to be in the on state during the on-time of the PWM signal,
wherein the controller is configured to provide the first control instruction when the DCO is in the on state and when the duty cycle of the PWM signal is above a threshold duty cycle.

13. The oscillator circuit of claim 1, wherein the DCO is configured to receive the first feedback signal, and apply a frequency offset to the output signal based on the first feedback signal, wherein the frequency offset is proportional to the value of the first feedback signal.

14. An oscillator circuit comprising:
a digitally controlled oscillator (DCO) configured to generate an oscillator output signal at a first frequency;
a digital feedback circuit configured to receive the output signal and output a feedback signal, wherein the DCO is configured to receive the feedback signal, and wherein the first frequency of the output signal is based at least in part on a value of the feedback signal; and
wherein the digital feedback circuit is configured to, in response to a control instruction:
measure the first frequency of the output signal; and
adjust the value of the feedback signal to reduce an error between the first frequency and a target frequency.

15. The oscillator circuit of claim 14, further comprising a controller, wherein the controller is configured to provide a clock signal to the DCO, wherein the DCO is configured to toggle between an on state and an off state in response to the clock signal; and
wherein the controller is configured to provide the control instruction to digital feedback circuit when the DCO is in the on state.

16. The oscillator circuit of claim 14, wherein the DCO is configured to:
receive a frequency control signal comprising a first frequency control value, wherein the output signal is generated at the first frequency in response to the first frequency control value of the frequency control signal; and
apply a frequency offset to the output signal based on the first feedback signal, wherein the frequency offset is proportional to the value of the first feedback signal.

17. The oscillator of claim 16, wherein the frequency control signal comprises a sequence of discrete frequency control values ranging from the first frequency control value to a second frequency control value,
wherein DCO is configured to generate the output signal at an instantaneous frequency corresponding to a current value of the frequency control signal, and
wherein the controller is configured provide the control instruction to the digital feedback circuit when the current value of frequency control signal corresponds to the first frequency control value.

18. The oscillator of claim 14, wherein the DCO is configured to generate the output signal at the first frequency in response to the value of the feedback signal, wherein the first frequency is proportional to the value of the feedback signal.

19. A method of generating an oscillator output signal, the method comprising:
generating, based on a frequency control signal, an oscillator output signal, the frequency control signal comprising a first frequency control value, wherein the output signal is generated at a first frequency in response to the first frequency control value of the frequency control signal, wherein the first frequency is dependent on, or based at least in part on, a value of a first feedback signal; and
in response to a first control instruction:
measuring the first frequency of the output signal; and
adjusting the value of the first feedback signal to reduce an error between the first frequency and a first target frequency.

20. A method of generating an oscillator output signal, the method comprising:
generating, based on a feedback signal, an oscillator output signal at a first frequency, wherein the first frequency of the output signal is based at least in part on a value of the feedback signal; and
in response to a control instruction:
measuring the first frequency of the output signal; and
adjusting the value of the feedback signal to reduce an error between the first frequency and a target frequency.
